(19) United States
(12) Patent Application Publication
(10) Pub. No.: US 2015/0262316 A1
(43) Pub. Date: Sep. 17, 2015

(54) POWER RATE CALCULATION METHOD AND POWER RATE CALCULATION DEVICE

(71) Applicant: Panasonic Intellectual Property Management Co., Ltd., Osaka (JP)

(72) Inventors: MAHDI BEHRANGRAD, Osaka (JP); YASUYUKI SHINTANI, Hyogo (JP); DAIGO SENOO, Osaka (JP); SATOSHI TSUJIMURA, Hyogo (JP)

(21) Appl. No.: 14/641,149

(22) Filed: Mar. 6, 2015

(30) Foreign Application Priority Data
Mar. 14, 2014 (JP) 2014-051836

(51) Int. Cl. G06Q 50/06; G06Q 30/02; G01R 21/00

(52) U.S. Cl. CPC G06Q 50/06; G01R 21/00; G06Q 30/0283

(57) ABSTRACT

A power rate calculation method for used in a facility that has the plurality of privately-used areas and a common area, one or more power generators are installed in the common area, includes: obtaining a plurality of first power amounts consumed by each of the privately-used areas, detecting whether or not a second power amount generated by the one or more power generators is larger than or equal to a third power amount consumed by both of the plurality of privately-used areas and the common area; and calculating the power rates from the plurality of first power amounts by applying a first rate structure when the second power amount is larger than or equal to the third power amount and by applying a second rate structure that is different from the first rate structure when the second power amount is smaller than the third power amount.

### BACKGROUND

1. Technical Field

The present disclosure relates to a power rate calculation method and a power rate calculation device for used in a facility in which one or more power generators are installed in a common area.

2. Description of the Related Art

Japanese Unexamined Patent Application Publication No. 2013-58046 discloses electricity rate calculation device and method that calculate a total power amount of power that is used in plural places and an electricity rate thereof.

### SUMMARY

However, it is not easy to appropriately calculate power rates of privately-used areas of a facility in which one or more power generators are installed in a common area.

One non-limiting and exemplary embodiment provides a power rate calculation method that enable appropriate calculation of power rates of privately-used areas of a facility in which one or more power generators are installed in a common area.

In one general aspect, the techniques disclosed here feature a power rate calculation method for used in a facility that has the plurality of privately-used areas and a common area, one or more power generators are installed in the common area, the method includes obtaining a plurality of first power amounts consumed by each of the privately-used areas in a prescribed period, detecting whether or not a second power amount generated by the one or more power generators is larger than or equal to a third power amount consumed by both of the plurality of privately-used areas and the common area in each unit time in the prescribed period, and calculating the power rates in the prescribed period from the plurality of first power amounts by applying a first rate structure when the second power amount is larger than or equal to the third power amount and by applying a second rate structure that is different from the first rate structure when the second power amount is smaller than the third power amount.

The present disclosure enables appropriate calculation of power rates of privately-used areas of a facility in which one or more power generators are installed in a common area.

It should be noted that general or specific embodiments may be implemented as a system, a device, a method, an integrated circuit, a computer program, a non-transitory recording medium such as a CD-ROM that is readable by a computer, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram of a housing complex according to a first embodiment;

FIG. 2 is a configuration diagram of the housing complex and a power system according to the first embodiment;

FIG. 3 is a graph that represents a first example of a change of a power state according to the first embodiment;

FIG. 4 is a graph that represents a second example of the change of the power state according to the first embodiment;

FIG. 5 is a diagram that illustrates a power rate of the power system according to the first embodiment;

FIG. 6 is a diagram that illustrates a role of a service provider according to the first embodiment;

FIG. 7 is a configuration diagram of a power rate calculation system according to the first embodiment;

FIG. 8 is an arrangement diagram of elements of the power rate calculation system according to the first embodiment;

FIG. 9 is a flowchart that illustrates an operation of selective applications of plural rate structures of the power rate calculation system according to the first embodiment;

FIG. 10 is a diagram that illustrates a power transmission cost according to the first embodiment;

FIG. 11 is a diagram that illustrates a power generation cost according to the first embodiment;

FIG. 12 is a diagram that illustrates a first specific example according to the first embodiment;

FIG. 13 is a diagram that illustrates a second specific example according to the first embodiment;

FIG. 14 is a configuration diagram of a power rate calculation system according to a second embodiment;

FIG. 15 is a flowchart that illustrates an operation of selective applications of plural rate structures of the power rate calculation system according to the second embodiment;

FIG. 16 is a diagram that illustrates a power transmission cost according to the second embodiment;

FIG. 17 is a diagram that illustrates a power generation cost according to the second embodiment;

FIG. 18 is a diagram that illustrates a specific example according to the second embodiment;

FIG. 19 is a flowchart that illustrates an operation of the power rate calculation system according to the second embodiment;

FIG. 20 is a configuration diagram of a power rate calculation system according to a third embodiment;

FIG. 21 is an arrangement diagram of elements of the power rate calculation system according to the third embodiment;

FIG. 22 is a configuration diagram of a power rate calculation system according to a fourth embodiment;

FIG. 23 is a flowchart that illustrates an operation of the power rate calculation system according to the fourth embodiment;

FIG. 24 is a configuration diagram of a power rate calculation system according to a fifth embodiment;

FIG. 25 is a diagram that illustrates a first output example according to the fifth embodiment; and

FIG. 26 is a diagram that illustrates a second output example according to the fifth embodiment.

### DETAILED DESCRIPTION

### Underlying Knowledge Forming Basis of the Present Disclosure

The present inventor found problems with calculation of power rates of privately-used areas of a facility in which a power generation system is installed in a common area. A specific description will be made below.

In recent years, there are cases where a power generation system such as a photovoltaic power generation system, which includes one or more power generators, is introduced to a detached house. For example, in a case where the photovoltaic power generation system is introduced to the detached house, solar panels are mounted on a roof of the detached house. Then, the photovoltaic power generation system that is introduced to the detached house generates power by using sunlight that shines on the solar panels.

Meanwhile, there are housing complexes that have privately-used areas and common areas. The housing complex is also referred to as condominium, apartment complex, or residential complex. In many cases, the privately-used area of the housing complex has no roof. Thus, the solar panels are mounted on a rooftop that is included in the common areas, for example. That is, in the housing complex, there is a case where the photovoltaic power generation system that is shared by plural privately-used areas is installed in the common area. The photovoltaic power generation system may be used in the housing complex in such a mode.

However, it is not easy to appropriately calculate power rates of the respective privately-used areas of the housing complex in which a power generation system such as the photovoltaic power generation system is installed in the common area. Specifically, a power meter of the privately-used area measures a power amount that is input to the privately-used area without distinguishing supply sources of power. Thus, it is difficult to reflect, in the power rate, use of generated power of the power generation system in power consumption of the privately-used area.

Further, in a detached house, the power generation system is installed within a management range of the detached house. Thus, the power meter may detect the sum of the power generated by the power generation system and the consumed power. This allows the power generated by the power generation system to be distinguished from power that is purchased from a system. However, in the housing complex, because the power generation system is installed in the common area that is outside of a management range of the privately-used areas. Thus, the power that is purchased from the power system may not be distinguished from the power generated by the power generation system. Therefore, it is difficult to omit the power amount from the power generation system in calculation of the power rate, and it is difficult to calculate an appropriate power rate.

That is, it is difficult to calculate appropriate power rates of the respective privately-used areas of a facility such as the housing complex in which the power generation system is installed in the common area. Further, because it is difficult to calculate an appropriate power rate in such a facility, there are cases where the power generation system such as the photovoltaic power generation system is not introduced and cases where utilization of natural energy is hindered.

A power rate calculation method according to one aspect of the present disclosure is a power rate calculation method for used in a facility that has the plurality of privately-used areas and a common area, one or more power generators are installed in the common area, the method includes obtaining a plurality of first power amounts consumed by each of the privately-used areas in a prescribed period, detecting whether or not a second power amount generated by the one or more power generators is larger than or equal to a third power amount consumed by both of the plurality of privately-used areas and the common area in each unit time in the prescribed period and calculating the power rates in the prescribed period from the plurality of first power amounts by applying a first rate structure when the second power amount is larger than or equal to the third power amount and by applying a second rate structure that is different from the first rate structure when the second power amount is smaller than the third power amount.

This allows the power rate calculation method to selectively apply plural rate structures in accordance with whether or not the power consumption is covered by the one or more power generators of the common area. That is, the power rate calculation method may reflect, in the power rates, use of the generated power of the one or more power generators in the power consumption of the privately-used areas. Accordingly, the power rate calculation method may appropriately calculate the power rates of the privately-used areas of the facility in which the one or more power generators are installed in the common area and may facilitate use of natural energy.

In an aspect of the present disclosure, the first rate structure has a lower power transmission cost than that of the second rate structure.

In an aspect of the present disclosure, a power transmission cost of the first rate structure is free and a power transmission cost of the second rate structure is charged.

In an aspect of the present disclosure, the first rate structure includes a power generation cost of the one or more power generators and the second rate structure includes the power generation cost of a power system.

In an aspect of the present disclosure, measuring a fourth power amount from a power system to the facility in each unit time in the prescribed period and detecting whether or not the second power amount is larger than or equal to the third power amount based on the fourth power.

In an aspect of the present disclosure, measuring a fifth power amount input to the common area in each unit time and calculating the power rates based on the fifth power amount.

In an aspect of the present disclosure, applying the second rate structure when the fifth power amount that is zero or smaller, and a third rate structure that is different from the first rate structure and the second rate structure when the fifth power amount is larger than zero.

In an aspect of the present disclosure, detecting whether or not the second power amount is larger than or equal to the third power amount based on the plurality of first power amounts and the fifth power amount in each unit time.

In an aspect of the present disclosure, calculating the power rates based on whether or not each of a plurality of tenants of the plurality of respective privately-used areas selects to use the one or more power generators.

In an aspect of the present disclosure, applying the first rate structure and the second rate structure when the power rate of the privately-used area is calculated for the tenant that selects to use the one or more power generators, and a fourth rate structure that is different from the first rate structure and the second rate structure when the power rate of the privately-used area is calculated for the tenant that does not select to use the one or more power generators.

In an aspect of the present disclosure, a power rate calculation device for used in a facility that has the plurality of privately-used areas and a common area, one or more power generators are installed in the common area, the device includes one or more memories; and circuitry operative to obtain a plurality of first power amounts consumed by each of the privately-used areas in a prescribed period.

Accordingly, a power rate calculation system according to one aspect of the present disclosure is a power rate calculation system that calculates power rates of plural privately-used areas in a facility that has the plural privately-used areas, plural first power meters that measure plural respective first power amounts that are consumed by the plural privately-used areas in a prescribed period, and a common area in which a power generation system is installed, the power rate calculation system including: a detection device that detects whether or not a second power amount that is generated by the power generation system is larger than or equal to a third power amount that is consumed by the plural privately-used areas and the common area in each unit time in the prescribed period; and a calculation device that calculates the power rates in the prescribed period from the plural respective first power amounts by applying a first rate structure to a first unit time in which detection is made that the second power amount is larger than or equal to the third power amount and by applying a second rate structure that is different from the first rate structure to a second unit time in which detection is made that the second power amount is smaller than the third power amount.

This allows the power rate calculation system to selectively apply plural rate structures in accordance with whether or not the power consumption is covered by the power generation system of the common area. That is, the power rate calculation system may reflect, in the power rates, use of the generated power of the power generation system in the power consumption of the privately-used areas. Accordingly, the power rate calculation system may appropriately calculate the power rates of the privately-used areas of the facility in which the power generation system is installed in the common area and may facilitate use of natural energy.

In an aspect of the present disclosure, the calculation device may calculate the power rates by calculating unit prices that correspond to the plural first power amounts by respectively applying the first rate structure and the second rate structure to the first unit time and the second unit time and multiplying the calculated unit prices by the plural respective first power amounts.

This allows the power rate calculation system to determine an appropriate unit price in accordance with whether or not the power consumption is covered by the power generation system of the common area. Further, the power rate calculation system may appropriately calculate the power rates by multiplying the power consumption by the unit price.

In an aspect of the present disclosure, the calculation device may apply the first rate structure that has a lower power transmission cost than that of the second rate structure to the first unit time.

This allows the power rate calculation system to calculate the power rates in which the power transmission cost is reduced in a case where a power system is not used.

In an aspect of the present disclosure, the calculation device may apply the first rate structure in which a power transmission cost is free to the first unit time and may apply the second rate structure in which the power transmission cost is charged to the second unit time.

This allows the power rate calculation system to calculate the power rates in which the power transmission costs are omitted in a case where a power system is not used.

In an aspect of the present disclosure, the calculation device may apply the first rate structure that includes a power generation cost of the power generation system to the first unit time and may apply the second rate structure that includes the power generation cost of a power system to the second unit time.

This allows the power rate calculation system to selectively apply the power generation cost of the power generation system and the power generation cost of the power system.

In an aspect of the present disclosure, the detection device may detect presence or absence of a reverse power flow from the whole facility into a power system to detect whether or not the second power amount is larger than or equal to the third power amount.

This allows the power rate calculation system to detect whether or not the power consumption is covered by the power generation system of the common area.

In an aspect of the present disclosure, the detection device may be a second power meter that measures a fourth power amount from a power system to the whole facility in each unit time in the prescribed period to detect whether or not the second power amount is larger than or equal to the third power amount.

This allows the power rate calculation system to appropriately detect the power amount from the power system and to appropriately detect whether or not the power consumption is covered by the power generation system of the common area.

In an aspect of the present disclosure, the power rate calculation system may further include a third power meter that measures a fifth power amount that is input to the common area in each unit time, in which the calculation device may calculate the power rates based on the fifth power amount that is measured by the third power meter in each unit time.

This allows the power rate calculation system to appropriately calculate the power rates based on the power amounts that reflect the generated power amount of the power generation system and the power consumption amount in the common area.

In an aspect of the present disclosure, the calculation device may apply the second rate structure to the second unit time in a case where the fifth power amount that is measured by the third power meter in the second unit time is zero or smaller and may apply a third rate structure that is different from the first rate structure and the second rate structure to the second unit time in a case where the fifth power amount that is measured by the third power meter in the second unit time is larger than zero.

This allows the power rate calculation system to calculate the power rates of the privately-used areas, for example, while omitting the consumption amount of power that flows into the common area.

In an aspect of the present disclosure, the plural first power meters may measure the plural respective first power amounts in each unit time in the prescribed period, and the detection device may detect in each unit time whether or not the second power amount is larger than or equal to the third power amount based on the plural first power amounts that are measured by the plural first power meters in each unit time and the fifth power amount that is measured by the third power meter in each unit time.

This allows the power rate calculation system to appropriately detect that the power consumption is covered by the power generation system of the common area without limiting a location of the detection device.

In an aspect of the present disclosure, the calculation device may calculate the power rates based on whether or not each of plural tenants of the plural respective privately-used areas selects to use the power generation system.

This allows the power rate calculation system to appropriately calculate the power rates based on whether or not use of the power generation system is selected.

In an aspect of the present disclosure, the calculation device may respectively apply the first rate structure and the second rate structure to the first unit time and the second unit time in a case where the power rate of the privately-used area is calculated for the tenant that selects to use the power generation system and may apply a fourth rate structure that is different from the first rate structure and the second rate structure in a case where the power rate of the privately-used area is calculated for the tenant that does not select to use the power generation system.

This allows the power rate calculation system to calculate the power rates by using the rate structure that corresponds to the tenant that does not select to use the power generation system and the rate structure that corresponds to the tenant that selects to use the power generation system.

Further, a power rate calculation method according to one aspect of the present disclosure is a power rate calculation method of calculating power rates of plural privately-used areas in a facility that has the plural privately-used areas, plural first power meters that measure plural respective first power amounts that are consumed by the plural privately-used areas in a prescribed period, and a common area in which a power generation system is installed, the power rate calculation method including: a detection step of detecting whether or not a second power amount that is generated by the power generation system is larger than or equal to a third power amount that is consumed by the plural privately-used areas and the common area in each unit time in the prescribed period; and a calculation step of calculating the power rates in the prescribed period from the plural first power amounts by applying a first rate structure to a first unit time in which detection is made that the second power amount is larger than or equal to the third power amount and by applying a second rate structure that is different from the first rate structure to a second unit time in which detection is made that the second power amount is smaller than the third power amount.

This allows the power rate calculation system to selectively apply plural rate structures in accordance with whether or not the power consumption is covered by the power generation system of the common area. That is, the power rates reflect use of the generated power of the power generation system in the power consumption of the privately-used areas. This enables appropriate calculation of the power rates of the privately-used areas of the facility in which the power generation system is installed in the common area and enables facilitation of use of natural energy.

It should be noted that general or specific embodiments may be implemented as a system, a device, a method, an integrated circuit, a computer program, a non-transitory recording medium such as a CD-ROM that is readable by a computer, or any selective combination thereof.

Embodiments will hereinafter be described in detail with reference to drawings. It should be noted that all the embodiments described below illustrate general or specific examples. Values, shapes, materials, elements, arrangement positions or connection manners of elements, steps, orders of steps, and so forth that are described in the following embodiments are merely illustrative and are not intended to limit the present disclosure. Further, the elements that are not described in the independent claims that provide the most superordinate concepts among the elements in the following embodiments will be described as arbitrary elements.

Further, a power amount usually means an integrated value of power in a prescribed time and corresponds to energy. Herein, an amount of power may be referred to as power amount. Further, the power and the power amount (energy) mutually correspond. Thus, herein, the power may be used as the meaning of the power amount (energy), and the power amount may be used as the meaning of the power. Further, the power and the power amount may mean values thereof.

Further, a flow of power into a power system may be referred to as reverse power flow. Further, a flow of power from the power system may be referred to as normal power flow.

### First Embodiment

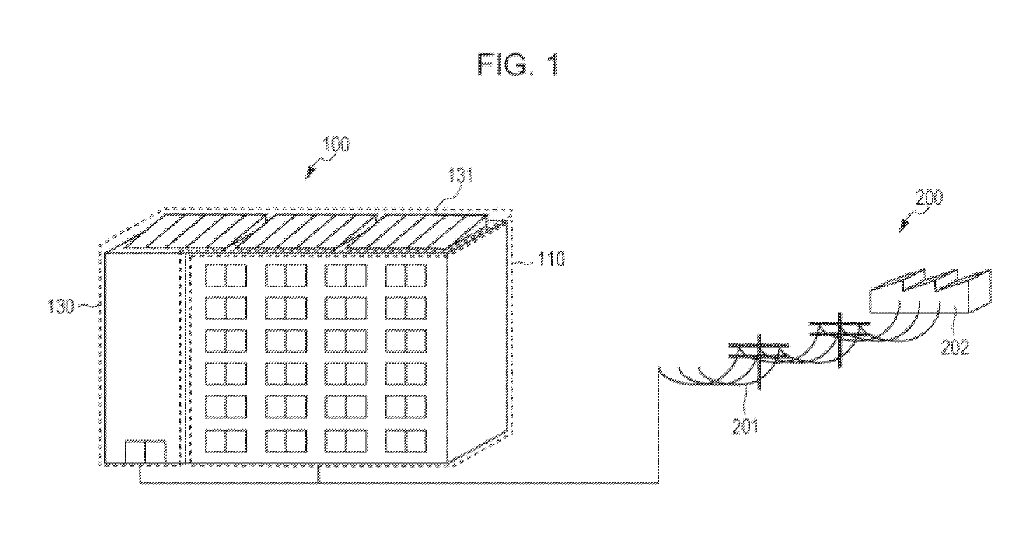

FIG. 1 is a schematic diagram of a housing complex and a power system according to a first embodiment. A housing complex 100 illustrated in FIG. 1 has a privately-used area 110 and a common area 130. More specifically, the privately-used area 110 includes plural privately-used areas. The common area 130 includes a photovoltaic power generation system 131. A power system 200 illustrated in FIG. 1 includes a power network 201 and a power plant 202. The power plant 202 corresponds to generation of power (power generation company), and the power network 201 corresponds to transmission and distribution of power (power transmission and distribution company).

For example, power may be supplied from the power system 200 to the privately-used area 110, or power may be supplied from the common area 130 that includes the photovoltaic power generation system 131 to the power system 200.

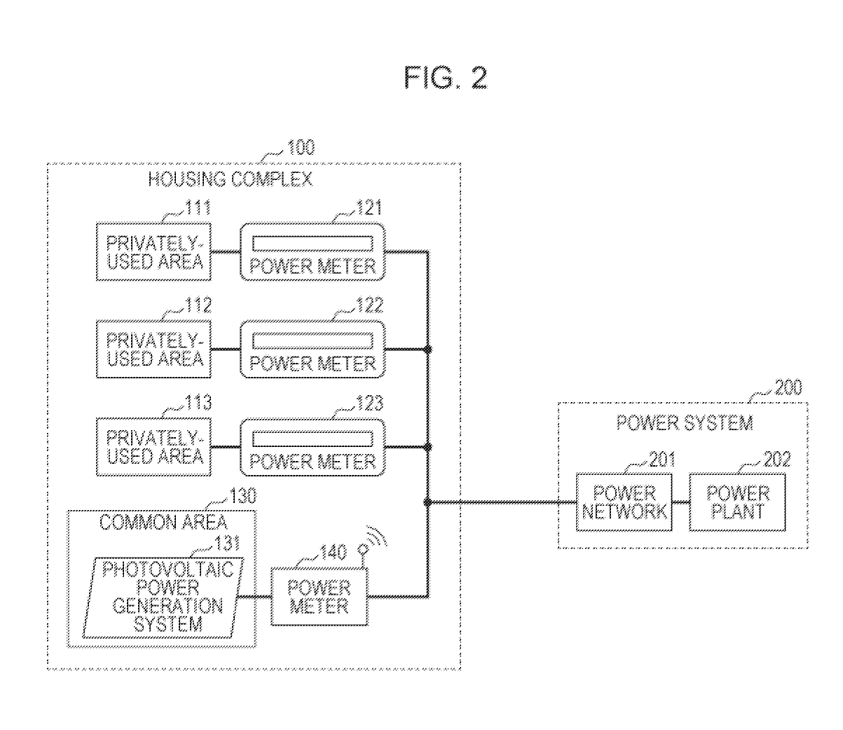

FIG. 2 is a configuration diagram of the housing complex 100 and the power system 200 that are illustrated in FIG. 1. In an example of FIG. 2, the housing complex 100 includes privately-used areas 111 to 113, the common area 130, power meters 121 to 123 and 140. In the example of FIG. 2, the housing complex 100 includes three privately-used areas 111 to 113 but may include four or more privately-used areas or only two or less privately-used areas. Further, as illustrated in FIG. 2, the power system 200 includes the power network 201 and the power plant 202.

The power meters 121 to 123 measure power amounts that are input to the privately-used areas 111 to 113 in a prescribed period without distinguishing supply sources of power. The prescribed period is one month, for example. That is, the power meter 121 measures a total power consumption amount of the privately-used area 111 in the prescribed period. Similarly, the power meter 122 measures the total power consumption amount of the privately-used area 112 in the prescribed period, and the power meter 123 measures the total power consumption amount of the privately-used area 113 in the prescribed period.

The power meter 140 measures the power amount that is input to the common area 130 in each unit time in the prescribed period. The common area 130 is provided with lights, an elevator, and so forth for common use. Those use power that is input to the common area 130.

Power that is generated by the photovoltaic power generation system 131 is used by the common area 130. In a case where the power that is generated by the photovoltaic power generation system 131 exceeds the power that is consumed by the common area 130, the power generated by the photovoltaic power generation system 131 is used by the privately-used areas 111 to 113. The power meter 140 also measures the power amount that is output from the common area 130 in each unit time. For example, selling of power to the power system 200 is executed based on the power amount that is output from the common area 130 in each unit time.

The unit time is 30 minutes, for example. More specifically, the power meter 140 measures the power amount that is input to the common area 130 for 30 minutes and the power amount that is output from the common area 130 and repeats such a measurement for 30 minutes. Here, the power meter 140 measures the power amount that is input to the common area 130 as a positive power amount and measures the power amount that is output from the common area 130 as a negative power amount. In a case where the positive-negative relationship is reversed, a substantially same configuration is realized.

The power meter 140 is a power meter that has a communication function, for example. The power meter that has a communication function is also referred to as smart meter. The power meter 140 may measure the power amount for each 30 minutes and may output the power amount that is measured for each 30 minutes. The power meters 121 to 123 measure the respective power amounts that are consumed by the privately-used areas 111 to 113 for one month but do not manage the power consumption amounts for each 30 minutes.

The power meters 121 to 123 measure the power amounts that are consumed by the privately-used areas 111 to 113 without distinguishing supply sources of power. Further, the power meter 140 measures the power amount that is output from the common area 130 without distinguishing supply destinations of power. Thus, it is difficult to determine whether or not the power that is consumed by the privately-used areas 111 to 113 is the power that is output from the common area 130 only by the configuration illustrated in FIG. 2.

This is because an upstream side across the power meters 121 to 123 and 140 is managed by the system and thus the power within the housing complex may not be distinguished from the power from the system in a case where the reverse power flow to the upstream side of the power meter 140 once occurs.

Thus, for example, an operation form in which the whole power that is output from the common area 130 is sold to the power system 200, is used. In such an operation form, it is not assumed that output power from the common area 130 is directly allotted to the power consumption of the privately-used areas 111 to 113, but it is assumed that the power from the power system 200 is allotted thereto. That is, in such an operation form, the output power from the common area 130 is allotted to the power consumption of the privately-used areas 111 to 113 via the power system 200.

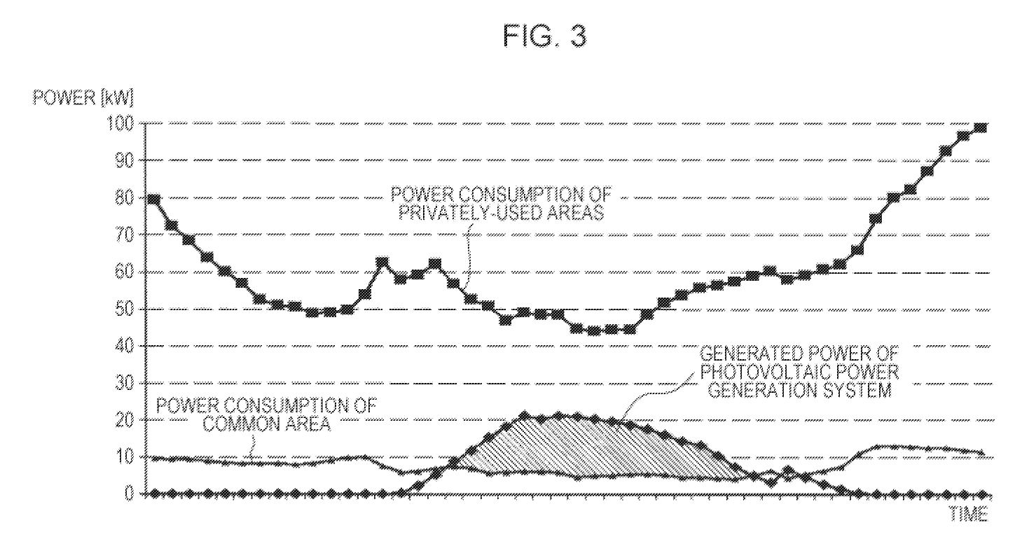

FIG. 3 is a graph that represents a first example of a change of a power state in the housing complex 100 that is illustrated in FIG. 1. As illustrated in FIG. 3, there is a case where the generated power of the photovoltaic power generation system 131 exceeds the power consumption of the common area 130. Such power is sold to the power system 200 in each unit time. Then, the power from the power system 200 is allotted to the power consumption of the privately-used areas 111 to 113.

However, in an example of FIG. 3, the generated power of the photovoltaic power generation system 131 does not exceed the total of the power consumption of the common area 130 and the power consumption of the privately-used areas 111 to 113. Thus, it is assumed that the whole generated power of the photovoltaic power generation system 131 is consumed inside the housing complex 100 not via the power system 200 and the power amount that corresponds to the shortage is supplied from the power system 200.

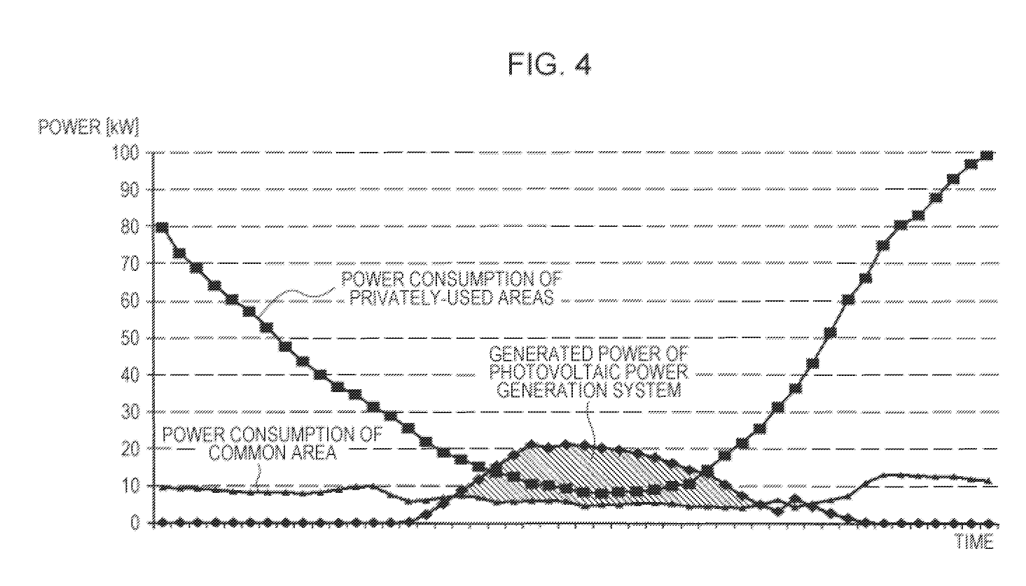

FIG. 4 is a graph that represents a second example of the change of the power state in the housing complex 100 that is illustrated in FIG. 1. In this example, the generated power of the photovoltaic power generation system 131 may exceed the total of the power consumption of the common area 130 and the power consumption of the privately-used areas 111 to 113. The power that exceeds the total of the power consumption of the common area 130 and the power consumption of the privately-used areas 111 to 113 in the generated power of the photovoltaic power generation system 131 is not consumed inside the housing complex 100 and reversely flows into the power system 200.

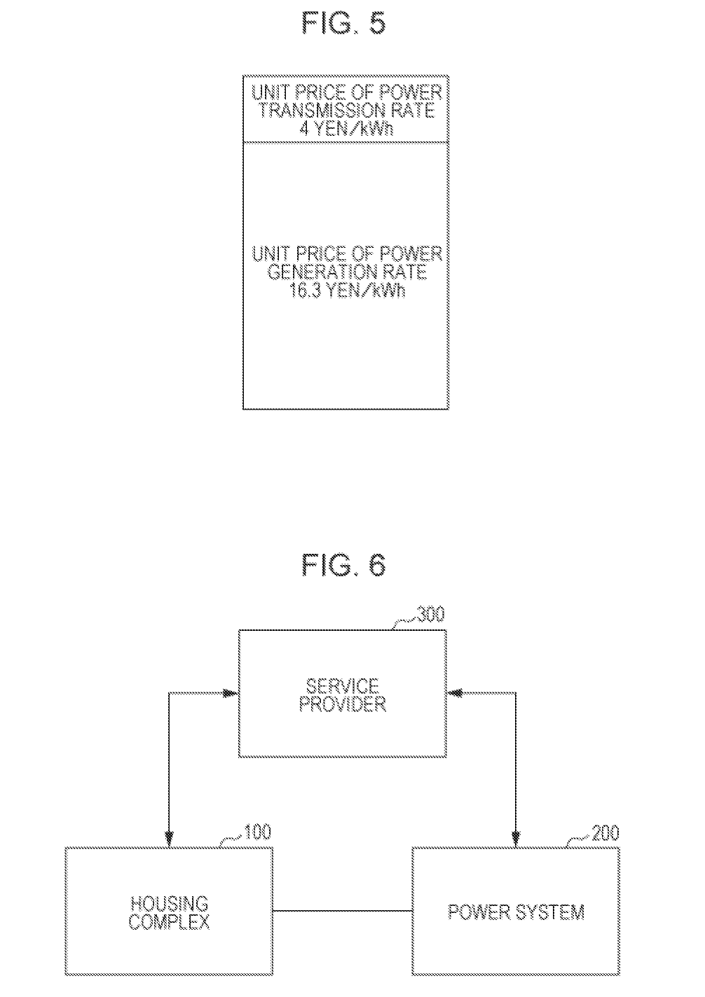

FIG. 5 is a diagram that illustrates a power rate of the power system 200 illustrated in FIG. 1. The power rate includes a power transmission rate and a power generation rate. The power transmission rate is a rate that corresponds to transmission of power and corresponds to a cost in accordance with use of the power network 201. The power transmission rate is also referred to as power transmission and distribution rate, power transmission cost, or grid cost. The power generation rate is a rate that corresponds to generation of power and corresponds to a cost in accordance with use of the power plant 202. The power generation rate is also referred to as energy rate, energy cost, and power generation cost.

For example, the unit price of the power transmission rate with respect to the power amount is 4 yen/kWh. The unit price of the power generation rate with respect to the power amount is 16.3 yen/kWh. As described above, the power transmission rate and the power generation rate may be determined in accordance with a used power amount.

Tenants of the housing complex 100 pay both of the power transmission rate and the power generation rate when the tenants purchase power from the power system 200. On the other hand, in a case where power is sold because of the reverse power flow, the power transmission rate is not paid, but only the power generation rate is paid. Accordingly, in an operation form in which the output power from the common area 130 is supplied to the privately-used areas 111 to 113 via the power system 200, a disadvantage that corresponds to the power transmission rate occurs in the housing complex 100.

FIG. 6 is a diagram that illustrates a role of a service provider with respect to the housing complex 100 and the power system 200 that are illustrated in FIG. 1. A service provider 300 is a company that supports an operation of power in the housing complex 100. The power rate that corresponds to the power consumption amount of the housing complex 100 may be paid to a company of the power system 200 via the service provider 300. Further, the power rate that corresponds to the power that is supplied to the power system 200 by the reverse power flow may be paid to the tenants of the housing complex 100 via the service provider 300.

It is matter of course that the tenants of the housing complex 100 may directly pay the power rate corresponding to the power consumption amount to the company of the power system 200 not via the service provider 300 and may directly receive the rate corresponding to the sold power amount from the company of the power system 200.

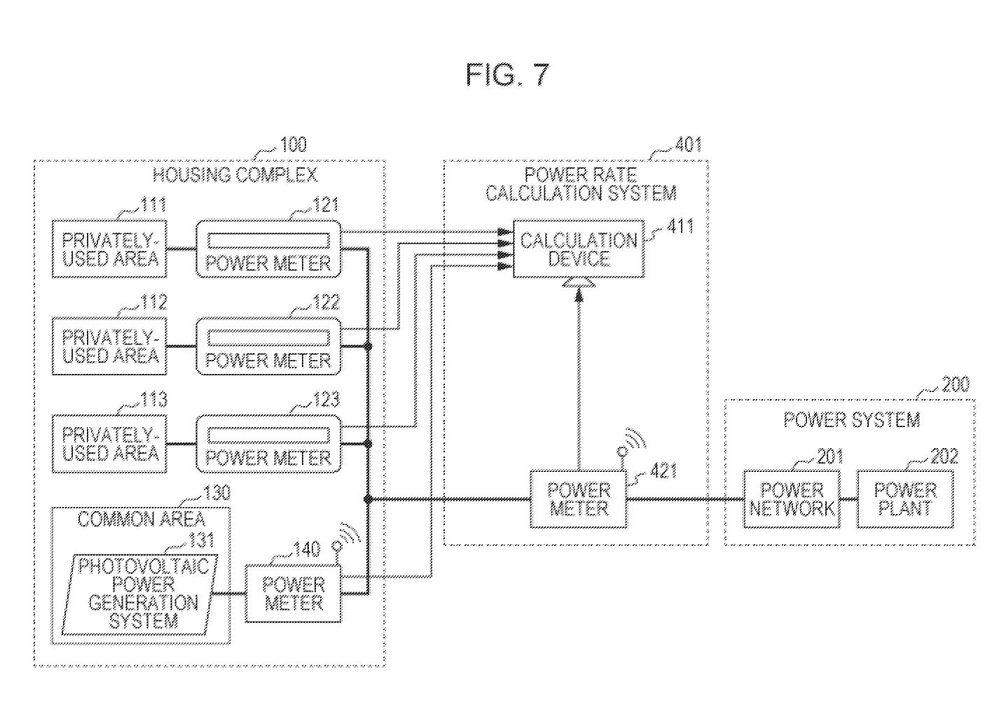

FIG. 7 is a configuration diagram of a power rate calculation system according to this embodiment. A power rate calculation system 401 illustrated in FIG. 7 includes a calculation device 411 and a power meter 421.

As described above, the power meters 121 to 123 measure the respective power consumption amounts of the privately-used areas 111 to 113 without distinguishing supply sources of power. Further, the power meter 140 measures the power amount that is output from the common area 130 without distinguishing supply destinations of power. Thus, it is difficult to detect whether or not the power network 201 is used only by the configuration illustrated in FIG. 2. Thus, the power rate calculation system 401 includes the power meter 421.

The power meter 421 is a power meter that measures the power amount that flows into the housing complex 100. The power meter 421 measures the whole power amount that flows into the housing complex 100 and is thus referred to as intake meter or main power meter. In this embodiment, the power meter 421 is a smart meter. Specifically, the power meter 421 measures the power amount that is input from the power system 200 to the housing complex 100 (the privately-used areas 111 to 113 and the common area 130) in each unit time in a prescribed period.

Further, in a case where the generated power of the photovoltaic power generation system 131 exceeds the power consumption of the privately-used areas 111 to 113 and the common area 130, power is output from the housing complex 100. The power meter 421 also measures the power amount that is output from the housing complex 100 in each unit time.

Here, the power meter 421 measures the power amount that is input from the power system 200 to the housing complex 100 as a positive power amount and measures the power amount that is output from housing complex 100 to the power system 200 as a negative power amount. In a case where the positive-negative relationship is reversed, a substantially same configuration is realized.

The calculation device 411 is a device that calculates the respective power rates of the privately-used areas 111 to 113 of the housing complex 100 and is a computer, for example. The calculation device 411 calculates the power rates of the privately-used areas 111 to 113 based on the power amounts that are measured by the power meters 121 to 123, 140, and 421. For example, the power meter 421 detects whether or not power from the power system 200 is actually used in each unit time. The calculation device 411 calculates the power rates by applying different rate structures to the unit time in which power from the power system 200 is used and to the unit time in which power from the power system 200 is not used. A more specific calculation method will be described below.

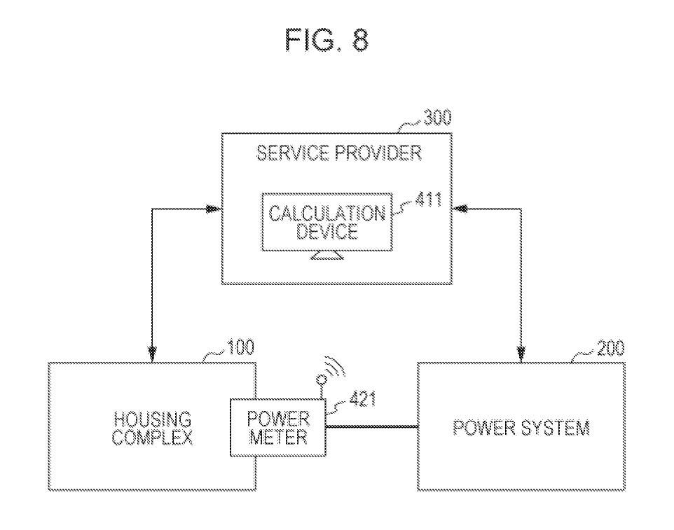

FIG. 8 is an arrangement diagram of the calculation device 411 and the power meter 421 of the power rate calculation system 401 illustrated in FIG. 7. For example, the calculation device 411 is arranged in a location of the service provider 300. The power meter 421 is arranged at a gateway of power of the housing complex 100.

This allows the power meter 421 to detect whether or not the reverse power flow from the whole housing complex 100 to the power system 200 occurs. That is, the power meter 421 may detect whether or not the total power consumption amount of the housing complex 100 is covered by a generated power amount of the photovoltaic power generation system 131.

The calculation device 411 that is arranged in the location of the service provider 300 obtains information about whether or not the total power consumption amount of the housing complex 100 is covered by the generated power amount of the photovoltaic power generation system 131 and may thereby calculate the power rates.

The calculation device 411 calculates the power rates based on not only the power amount that is measured by the power meter 421 but also the power amounts that are measured by the power meters 121 to 123 and 140. For example, the calculation device 411 may obtain the power amount that is measured by the power meter 140 and the power amount that is measured by the power meter 421 via a communication network. Further, the calculation device 411 may obtain the power amounts that are measured by the power meters 121 to 123 based on an input by a user of the power rate calculation system 401.

In an example of FIG. 8, the calculation device 411 is arranged in the location of the service provider 300. However, the calculation device 411 may be portable so that the user of the power rate calculation system 401 may input the power amounts to the calculation device 411 while visually recognizing the power meters 121 to 123. Further, in a case where the service provider 300 is not used, the calculation device 411 may be arranged in the housing complex 100, the power system 200, or another location.

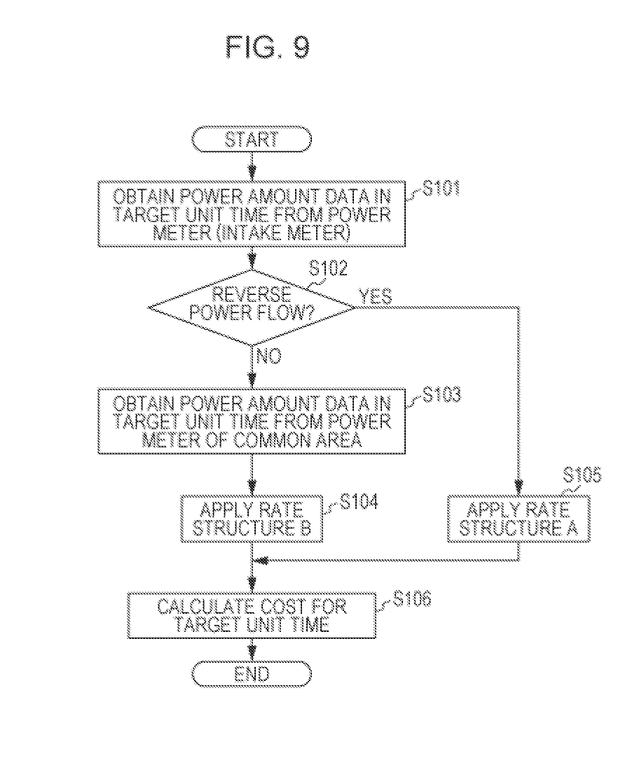

FIG. 9 is a flowchart that illustrates an operation of selective applications of plural rate structures of the power rate calculation system 401 illustrated in FIG. 7. The calculation device 411 of the power rate calculation system 401 selectively applies the plural rate structures in each unit time based on whether or not the total power consumption amount of the housing complex 100 is covered by the generated power amount of the photovoltaic power generation system 131. FIG. 9 illustrates the operation in such a case.

The calculation device 411 first obtains the power amount (power amount data) in a target unit time from the power meter 421 (S101). The calculation device 411 determines whether or not the reverse power flow from the housing complex 100 to the power system 200 occurs in the target unit time (S102).

Specifically, in a case where the power amount from the power system 200 to the housing complex 100 in the target unit time is expressed by i, the calculation device 411 determines whether or not i≦0 holds true. That is, the calculation device 411 determines whether or not the photovoltaic power generation system 131 covers the power consumption of the housing complex 100 in the target unit time. Here, the case of i=0 is dealt with similarly to a case of the reverse power flow.

In a case where the reverse power flow occurs in the target unit time (Yes in S102), the calculation device 411 applies a predetermined rate structure A to the target unit time (8105). In a case where the reverse power flow does not occur in the target unit time (No in S102), the calculation device 411 obtains the power amount (power amount data) in the target unit time from the power meter 140 of the common area 130 (S103). The calculation device 411 then applies a predetermined rate structure B to the target unit time (S104).

The calculation device 411 then calculates the cost for the target unit time based on the rate structure A or B that is selectively applied (S106).

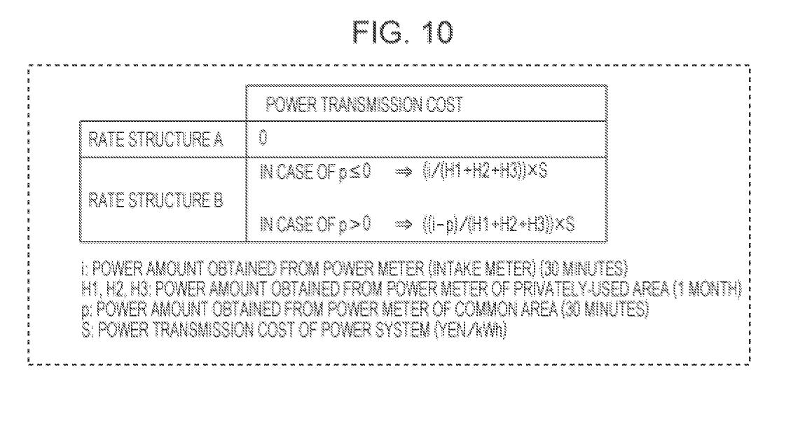

FIG. 10 is a diagram that illustrates the power transmission costs that are applied by the power rate calculation system 401 illustrated in FIG. 7. The calculation device 411 calculates the power transmission cost for each unit time, sums plural power transmission costs that are calculated with respect to plural unit times, and thereby calculates the unit price of the power transmission rate. FIG. 10 illustrates calculation formulas to calculate the power transmission cost for each unit time.

In a case where the reverse power flow occurs in the target unit time, the rate structure A is applied to the power transmission cost for the unit time. In a case where the reverse power flow occurs, the power network 201 of the power system 200 is not used. Thus, it is assumed that the power transmission cost does not occur. Accordingly, the power transmission cost of the rate structure A is calculated as zero.

In a case where the reverse power flow does not occur in the target unit time, the rate structure B is applied to the power transmission cost for the unit time. In a case where the reverse power flow does not occur, the power network 201 of the power system 200 is used. Thus, the calculation device 411 divides a power amount i that is measured by the power meter 421 by the total of the power consumption amounts H1 to H3 of the privately-used areas 111 to 113 and multiplies the resulting value by a power transmission cost S of the power system 200.

Further, it may not be appropriate to include the rate that corresponds to the power consumption amount of the common area 130 in the power rates of the privately-used areas 111 to 113. Thus, in a case where a power amount p that is measured by the power meter 140 is larger than zero, the calculation device 411 subtracts the power amount p that is measured by the power meter 140 from the power amount i that is measured by the power meter 421. The calculation device 411 then divides a power amount i−p that is obtained by the subtraction by the total of the power consumption amounts H1 to H3 of the privately-used areas 111 to 113 and multiplies the resulting value by the power transmission cost S of the power system 200.

In brief, in a case of p≦0, the power transmission cost of the rate structure B is calculated by (i/(H1+H2+H3))×S. In a case of p>0, the power transmission cost of the rate structure B is calculated by ((i−p)/(H1+H2+H3))×S. That is, the rate structure B includes two rate structures in which the power transmission costs are mutually different. In a case of p>0, the power transmission cost of the rate structure B may be calculated by (i/(H1+H2+H3+p))×S.

Formula 1 as below is a formula that is used by the power rate calculation system 401 illustrated in FIG. 7.

Power rate=(unit price of power rate)×(power amount obtained from power meter of privately used area)=(unit price of power generation rate+unit price of power transmission rate)×(power amount obtained from power meter of privately-used area)=(unit price of power generation rate+total of power transmission costs)×(power amount obtained from power meter of privately-used area) Formula (1):

For example, the power rate of the privately-used area 111 is calculated by (the unit price of the power rate)×(the power amount that is obtained from the power meter 121). In addition, the unit price of the power rate is calculated by (the unit price of the power generation rate)+(the unit price of the power transmission rate). Further, the unit price of the power transmission rate is calculated by the total of plural power transmission costs that correspond to plural unit times.

For example, the plural power transmission costs that correspond to the plural unit times are calculated based on FIGS. 9 and 10. The calculation device 411 of the power rate calculation system 401 multiplies the total of the plural calculated power transmission costs by the power consumption amounts of the privately-used areas 111 to 113. This allows the power rate calculation system 401 to calculate the power rates while proportionally dividing the power amount that flows from the power system 200 into the privately-used areas 111 to 113 with respect to the privately-used areas 111 to 113 based on the power consumption amounts.

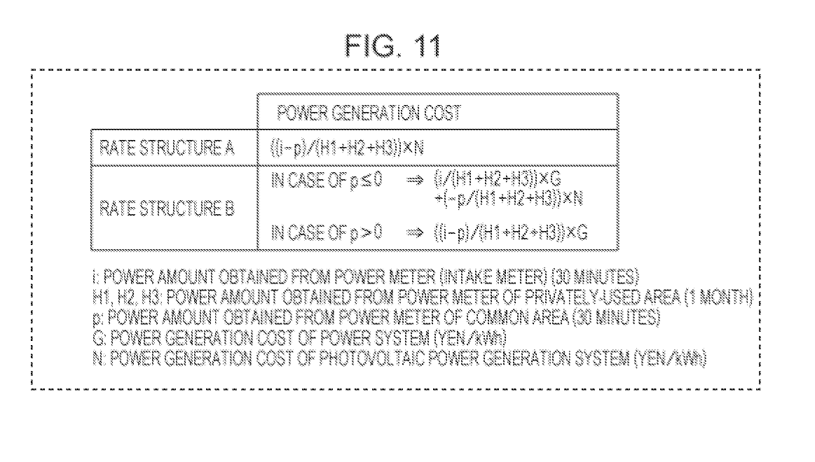

In FIGS. 10 and 11, the power transmission costs for each unit time are calculated in accordance with the power amounts. In addition, the power generation costs for each unit time may be calculated in accordance with the power amounts.

FIG. 11 is a diagram that illustrates the power generation costs that are calculated by the power rate calculation system 401 illustrated in FIG. 7. The power amounts that are consumed by the privately-used areas 111 to 113 in a target unit time are expressed by i−p based on the power amount p that is measured by the power meter 140 and the power amount i that is measured by the power meter 421.

In a case where the reverse power flow occurs in the target unit time, the rate structure A is applied. In this case, the whole power amount that is expressed by i−p corresponds to power from the photovoltaic power generation system 131. Accordingly, the power generation cost of the rate structure A is obtained by dividing the power amount i−p by the total of the power consumption amounts H1 to H3 of the privately-used areas 111 to 113 and multiplying the resulting value by the power generation cost N of the photovoltaic power generation system 131. Specifically, the power generation cost of the rate structure A is calculated by ((i−p)/(H1+H2+H3))×N.

In a case where the reverse power flow does not occur in the target unit time, the rate structure B is applied. Here, in a case where the power amount p that is measured by the power meter 140 is zero or smaller, the term i in i−p corresponds to power from the power system 200, and the term −p corresponds to power from the photovoltaic power generation system 131. Accordingly, in this case, the power generation cost of the rate structure B is calculated by (i/(H1+H2+H3))×G+(−p/(H1+H2+H3))×N by using the power generation cost G of the power system 200 and the power generation cost N of the photovoltaic power generation system 131.

Here, in a case where the power amount p that is measured by the power meter 140 is larger than zero, the whole power amount that is expressed by i−p corresponds to power from the power system 200. Thus, in a case where p is larger than zero, the power generation cost of the rate structure B is calculated by ((i−p)/(H1+H2+H3))×G. In this case, the power generation cost of the rate structure B may be calculated by (i/(H1+H2+H3+p))×G.

Further, in a case where the rate structure A is used for the calculation of the power generation cost for the target unit time, the calculation device 411 uses the power amount p that is measured by the power meter 140. Thus, the calculation device 411 obtains the power amount p that is measured by the power meter 140 before calculating the power generation cost of the rate structure A. Accordingly, in the operation illustrated in FIG. 9, the calculation device 411 may obtain the power amount p that is measured by the power meter 140 (S103) before a determination about the reverse power flow (S102).

Formula (2) as below is a second example of the calculation formula that is used by the power rate calculation system 401 illustrated in FIG. 7.

Power rate=(unit price of power rate)×(power amount obtained from power meter of privately used area)=(unit price of power generation rate+unit price of power transmission rate)×(power amount obtained from power meter of privately-used area)=(total of power generation costs+total of power transmission costs)×(power amount obtained from power meter of privately-used area) Formula (2)

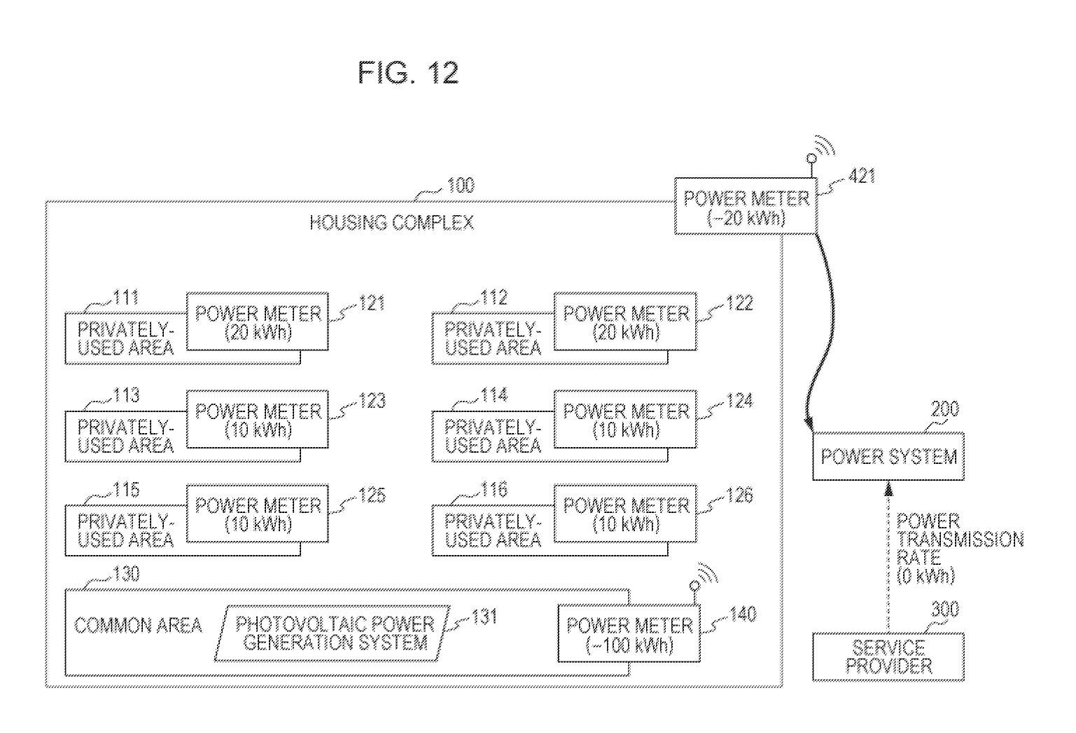

The example of Formula (2) is basically similar to the example of Formula (1). However, in the example of Formula (2), the unit price of the power generation rate is calculated by the total of plural power generation costs that correspond to plural unit times. The plural power generation costs that correspond to the plural unit times are calculated based on FIG. 11 and so forth. Accordingly, the calculation device 411 of the power rate calculation system 401 may appropriately calculate the power rates that correspond to the power generation cost of the supply source of power based on FIG. 12, Formula (2), and so forth.

The term 1/(H1+H2+H3) that is included in the calculation of the power transmission cost and the power generation cost for each unit time that are indicated in FIGS. 10 and 12 corresponds to data in a prescribed period. Thus, it is difficult to calculate the power transmission cost and the power generation cost for each unit time that are indicated in FIGS. 10 and 12 before the prescribed time elapses.

Thus, the calculation device 411 may not include 1/(H1+H2+H3) when the power transmission cost and the power generation cost for each unit time are calculated but may include 1/(H1+H2+H3) when the final power transmission cost and power generation cost that correspond to the prescribed period are calculated. That is, the calculation device 411 may integrate the power rate that occurs in the whole housing complex 100 in each unit time and may proportionally divide the integrated power rate in accordance with the power consumption amounts H1, H2, and H3 of the privately-used areas 111, 112, and 113 after the prescribed period elapses.

FIG. 12 is a diagram that illustrates a first specific example of a case where the power rate calculation system 401 illustrated in FIG. 7 calculates the power rates. The housing complex 100 illustrated in FIG. 12 further has privately-used areas 114 to 116 and power meters 124 to 126 compared to the housing complex 100 illustrated in FIG. 7. The power meter 124 measures the power consumption amount of the privately-used area 114, the power meter 125 measures the power consumption amount of the privately-used area 115, and the power meter 126 measures the power consumption amount of the privately-used area 116.

In the example of FIG. 12, the power meter 421 indicates −20 kWh. That is, the total power consumption amount of the housing complex 100 is covered by the generated power amount of the photovoltaic power generation system 131. In this case, the power network 201 of the power system 200 is not used. Accordingly, it is assumed that the power transmission rate does not occur. Thus, the power rate calculation system 401 calculates the power transmission rate to be paid from the service provider 300 to the power system 200 as zero yen.

Here, the power rate calculation system 401 may appropriately calculate the power rates based not on an operation form in which the whole power amount that is measured by the power meter 140 is sold but on an operation form in which the power amount that is measured by the power meter 421 is sold. That is, the power rate calculation system 401 may appropriately calculate the power rates based not on an operation form in which the whole power consumption of the privately-used areas 111 to 116 are covered by the power system 200 but on an operation form in which the power consumption of the privately-used areas 111 to 116 is covered by the photovoltaic power generation system 131.

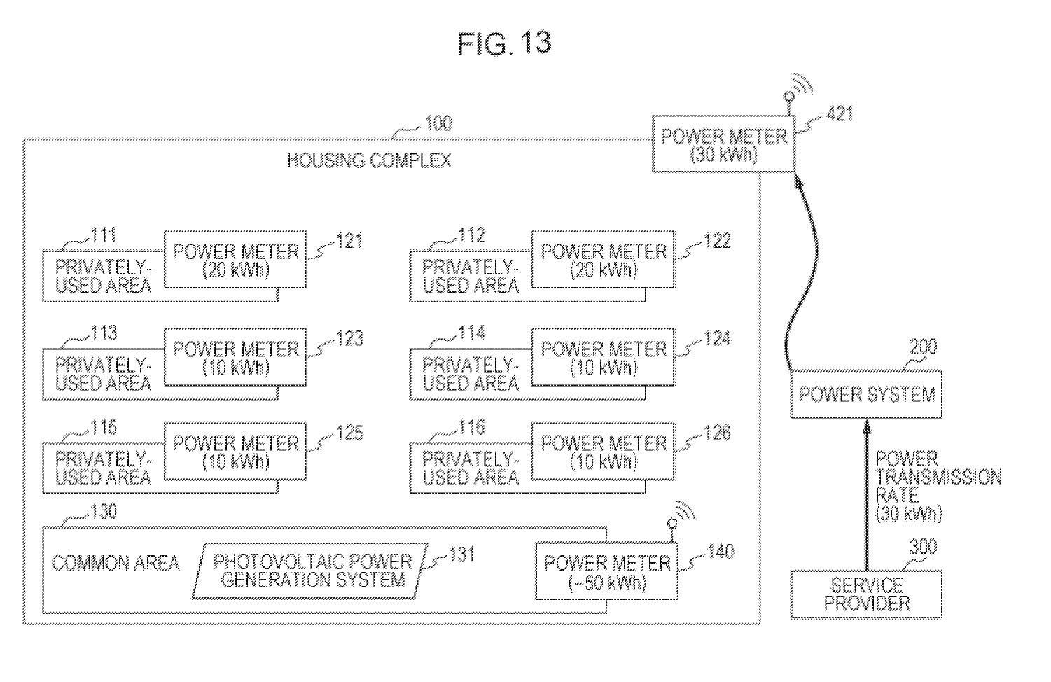

FIG. 13 is a diagram that illustrates a second specific example of a case where the power rate calculation system 401 illustrated in FIG. 7 calculates the power rates. The housing complex 100 illustrated in FIG. 13 is similar to the housing complex 100 illustrated in FIG. 12.

In the example of FIG. 13, the power meter 421 indicates 30 kWh. That is, a portion of the total power consumption amount of the housing complex 100 is not covered by the generated power amount of the photovoltaic power generation system 131. In this case, the power network 201 of the power system 200 is used. Accordingly, it is assumed that the power transmission rate that corresponds to 30 kWh occurs. Thus, the power rate calculation system 401 calculates the power transmission rate to be paid from the service provider 300 to the power system 200 in accordance with a power amount of 30 kWh.

In the example of FIG. 13, the power rate calculation system 401 may appropriately calculate the power rates based on the power amount that is measured by the power meter 421. Further, the power rate calculation system 401 may reflect, in the power rates, use of the generated power of the photovoltaic power generation system 131 in the power consumption.

As described above, the power rate calculation system 401 according to this embodiment selectively applies the plural rate structures in accordance with whether or not the power consumption of the housing complex 100 is covered by the photovoltaic power generation system 131. That is, the power rate calculation system 401 may reflect, in the power rates, use of the generated power of the photovoltaic power generation system 131 in the power consumption of the privately-used areas 111 to 113 and so forth.

Accordingly, the power rate calculation system 401 may appropriately calculate the respective power rates of the privately-used areas 111 to 113 and so forth of the housing complex 100 that includes the photovoltaic power generation system 131 and may facilitate use of natural energy.

In this embodiment, the power transmission cost of the rate structure A is free, but the power transmission cost of the rate structure B is charged. That is, the power transmission cost of the rate structure A is calculated as zero, but the power transmission cost of the rate structure B is calculated as zero or higher. However, the power transmission cost of the rate structure A may not be zero. For example, the power transmission cost that is lower than the power transmission cost of the rate structure B may be used as the power transmission cost of the rate structure A.

Further, the rate structures A and B described in this embodiment are merely examples, and other rate structures may be used. Substantially same rate structures as the rate structures A and B may be used, or substantially different rate structures may be used.

### Second Embodiment

A power rate calculation system according to this embodiment allows each of plural tenants of a housing complex to select whether or not to use a photovoltaic power generation system. Further, the power rate calculation system according to this embodiment appropriately calculate the power rates in accordance with selection of whether or not the photovoltaic power generation system is used.

Here, selecting not to use the photovoltaic power generation system and not selecting to use the photovoltaic power generation system have the same meaning and are not distinguished from each other. Further, the tenant that selects to use the photovoltaic power generation system is referred to as subscriber, and the tenant that selects not to use the photovoltaic power generation system is referred to as non-subscriber.

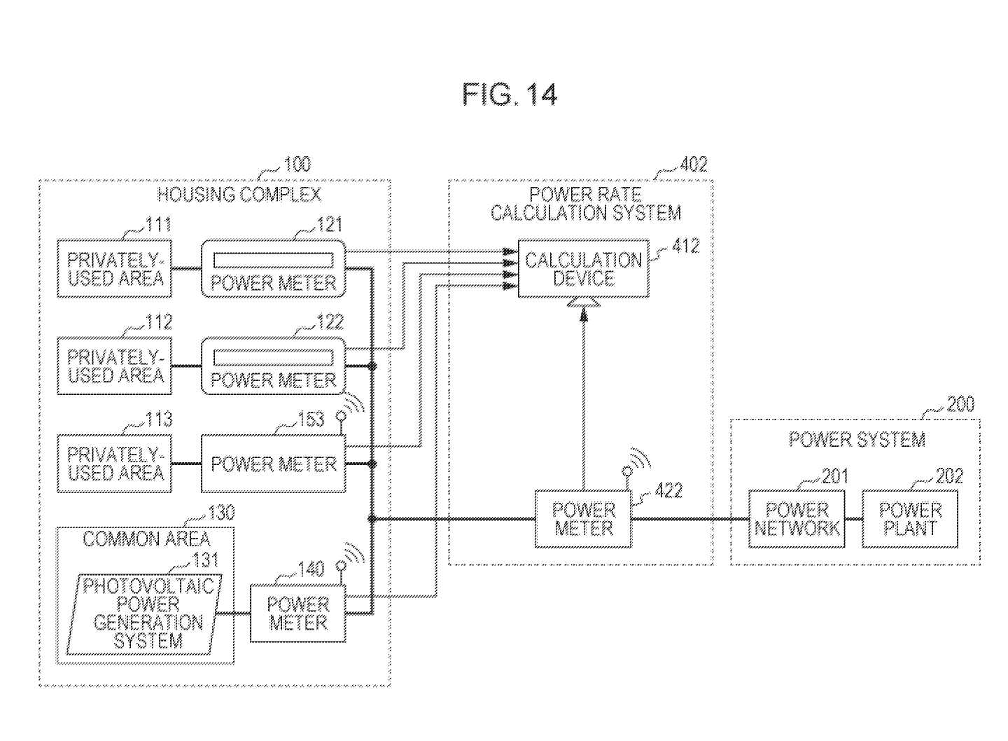

FIG. 14 is a configuration diagram of the power rate calculation system according to this embodiment. A power rate calculation system 402 illustrated in FIG. 14 includes a calculation device 412 and a power meter 422. Those are similar elements to the calculation device 411 and the power meter 421 that are described in the first embodiment. The calculation device 412 according to this embodiment calculates the power rates by following a calculation method that is partially different from the calculation device 411 described in the first embodiment.

In an example of FIG. 14, the tenants of the privately-used areas 111 and 112 select to use the photovoltaic power generation system 131. That is, the tenants of the privately-used areas 111 and 112 are the subscribers. On the other hand, the tenant of the privately-used area 113 selects not to use the photovoltaic power generation system 131. That is, the tenant of the privately-used area 113 is the non-subscriber.

Further, in the example of FIG. 14, a power meter 153 is used for a measurement of the power amount of the privately-used area 113. The power meter 153 may measure the power consumption amount of the privately-used area 113 in each unit time. The power meter 153 is a smart meter, for example.

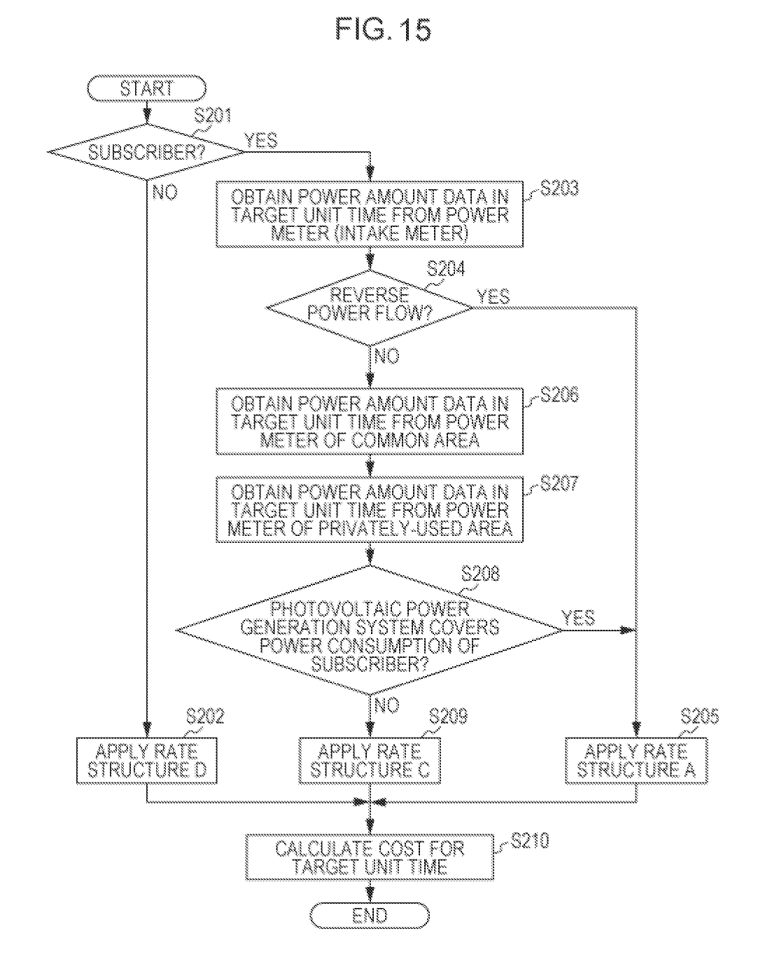

FIG. 15 is a flowchart that illustrates an operation of selective applications of plural rate structures of the power rate calculation system 402 illustrated in FIG. 14. The calculation device 412 first determines whether or not a target tenant is the subscriber based on information that is in advance input (S201). In a case where a determination is made that the target tenant is not the subscriber (No in S201), the calculation device 412 applies a rate structure D to a target unit time (S202).

In a case where a determination is made that the target tenant is the subscriber (Yes in S201), the calculation device 412 obtains the power amount (power amount data) in the target unit time from the power meter 422 (S203). Then, similarly to the calculation device 411 of the first embodiment, the calculation device 412 determines whether or not the reverse power flow from the housing complex 100 into the power system 200 occurs in the target unit time (S204).

In a case where the reverse power flow occurs in the target unit time (Yes in S204), the calculation device 412 applies the predetermined rate structure A to the target unit time (S205). In a case where the reverse power flow does not occur in the target unit time (No in S204), the calculation device 412 obtains the power amount (power amount data) in the target unit time from the power meter 140 of the common area 130 (S206). Further, in this case, the calculation device 412 obtains the power amount (power amount data) in the target unit time from the power meter 153 of the privately-used area 113 of the non-subscriber (S207).

The calculation device 412 then determines whether or not the photovoltaic power generation system 131 covers the power consumption of the subscriber based on the power amount that is measured by the power meter 422 and the power amount that is measured by the power meter 153 (S208). For example, in a case where the power amount that is measured by the power meter 422 in the target unit time is the power amount that is measured by the power meter 153 or smaller, the calculation device 412 determines that the photovoltaic power generation system 131 covers the power consumption of the subscriber.

In a case where the calculation device 412 determines that the photovoltaic power generation system 131 covers the power consumption of the subscriber (Yes in S208), the calculation device 412 applies the rate structure A to the target unit time (S205). On the other hand, in a case where the calculation device 412 determines that the photovoltaic power generation system 131 does not cover the power consumption of the subscriber (No in S208), the calculation device 412 applies a rate structure C to the target unit time (S209).

The calculation device 412 then calculates the cost for the target unit time based on the rate structure A, C, and D that are selectively applied (S210).

FIG. 16 is a diagram that illustrates the power transmission costs that are calculated by the power rate calculation system 402 illustrated in FIG. 14. The rate structure A of FIG. 16 is the same as the rate structure A of FIG. 10. Although the rate structure C is similar to the rate structure B, the power amount of the non-subscriber is omitted in the rate structure C.

Specifically, a term i−h3 is used in the rate structure C for the term i that corresponds to the used power amount from the power system 200 in the rate structure B. Further, a term h3 represents the power amount in the target unit time that is obtained from the power meter 153 of the privately-used area 113 of the non-subscriber. Further, a term (H1+H2) is used in the rate structure C for the term (H1+H2+H3) that corresponds to the total of the power consumption amounts of the privately-used areas 111 to 113 in the rate structure B. Accordingly, the power amount of the non-subscriber is omitted.

In the rate structure C of FIG. 16, in a case of p>0, ((i−p−h3)/(H1+H2))×S is used. However, ((i−h3)/(H1+H2+p))×S may be used.

The rate structure D is a rate structure for the non-subscriber. Here, the total of plural power transmission costs that correspond to plural unit times are used as the unit price of the power transmission rate. Thus, for convenience of description, the power transmission cost for each unit time of the rate structure D is indicated similarly to the power transmission costs of the rate structures A and B. However, the power transmission cost of the non-subscriber does not change in a prescribed period. Thus, the calculation device 412 may skip calculation of the power transmission cost for each unit time and may use the power transmission cost S of the power system 200 without any change.

The calculation device 412 calculates the power transmission cost for each unit time by selectively applying plural rate structures. The calculation device 412 calculates the power rates based on the calculation formula (1). This allows the calculation device 412 to calculate appropriate power rates with respect to the subscribers and the non-subscriber. Further, the calculation device 412 may calculate the power generation cost for each unit time similarly to the calculation device 411 of the first embodiment.

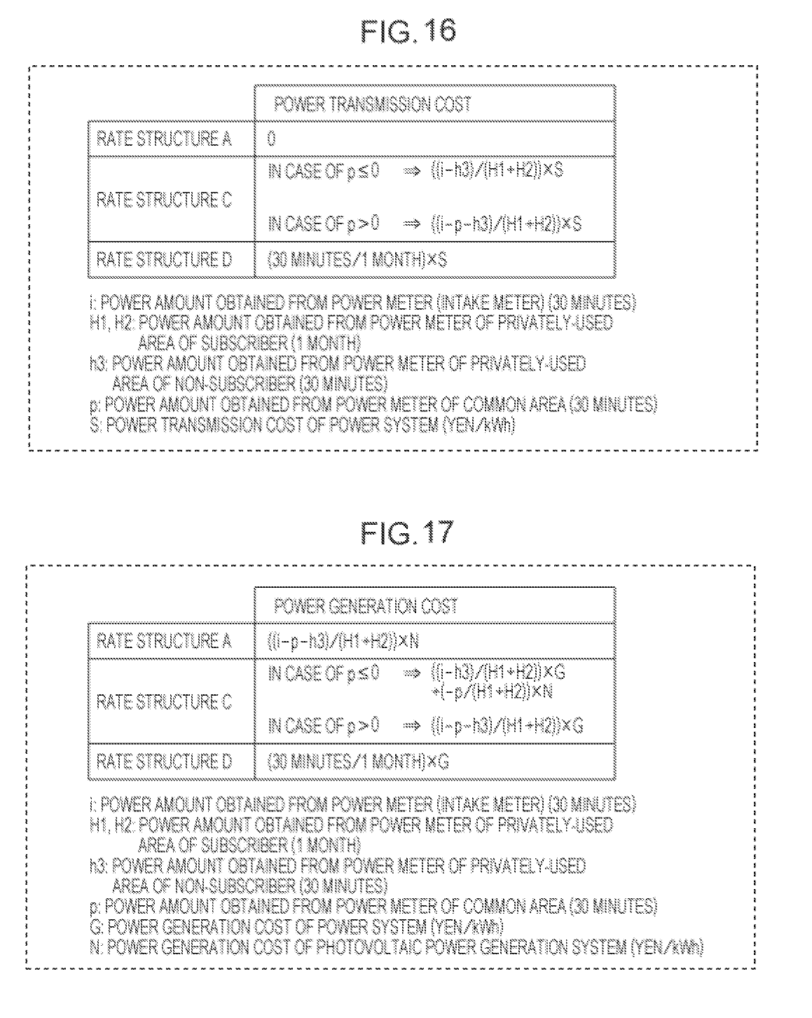

FIG. 17 is a diagram that illustrates the power generation costs that are calculated by the power rate calculation system 402 illustrated in FIG. 14. Although the rate structures A and C of FIG. 17 are similar to the rate structures A and B illustrated in FIG. 11, the power amount of the non-subscriber is omitted in the rate structures A and C of FIG. 17.

Specifically, the term i−h3 is used in the rate structures A and C of FIG. 17 for the term i that corresponds to the used power amount from the power system 200 in the rate structures A and B of FIG. 11. Further, the term (H1+H2) is used in the rate structures A and C of FIG. 17 for the term (H1+H2+H3) that corresponds to the total of the power consumption amounts of the privately-used areas 111 to 113 in the rate structures A and B of FIG. 11. Accordingly, the power amount of the non-subscriber is omitted.

In the rate structure C of FIG. 17, in a case of p>0, ((i−p−h3)/(H1+H2))×G is used. However, ((i−h3)/(H1+H2+p))×G may be used.

The rate structure D of FIG. 17 is a rate structure for the non-subscriber similarly to FIG. 16. FIG. 17 illustrates the power transmission cost for each unit time similarly to FIG. 16. With respect to the rate structure D, similarly to the power transmission cost, the calculation device 412 may skip calculation of the power generation cost for each unit time and may use the power generation cost G of the power system 200 as the unit price of the power generation rate without any change.

The calculation device 412 may calculate the power generation cost for each unit time by selectively applying plural rate structures based on the power generation costs illustrated in FIG. 17. The calculation device 412 may calculate the power rates based on the calculation formula (2) as below.

This allows the calculation device 412 to calculate further appropriate power rates with respect to the subscribers and the non-subscriber.

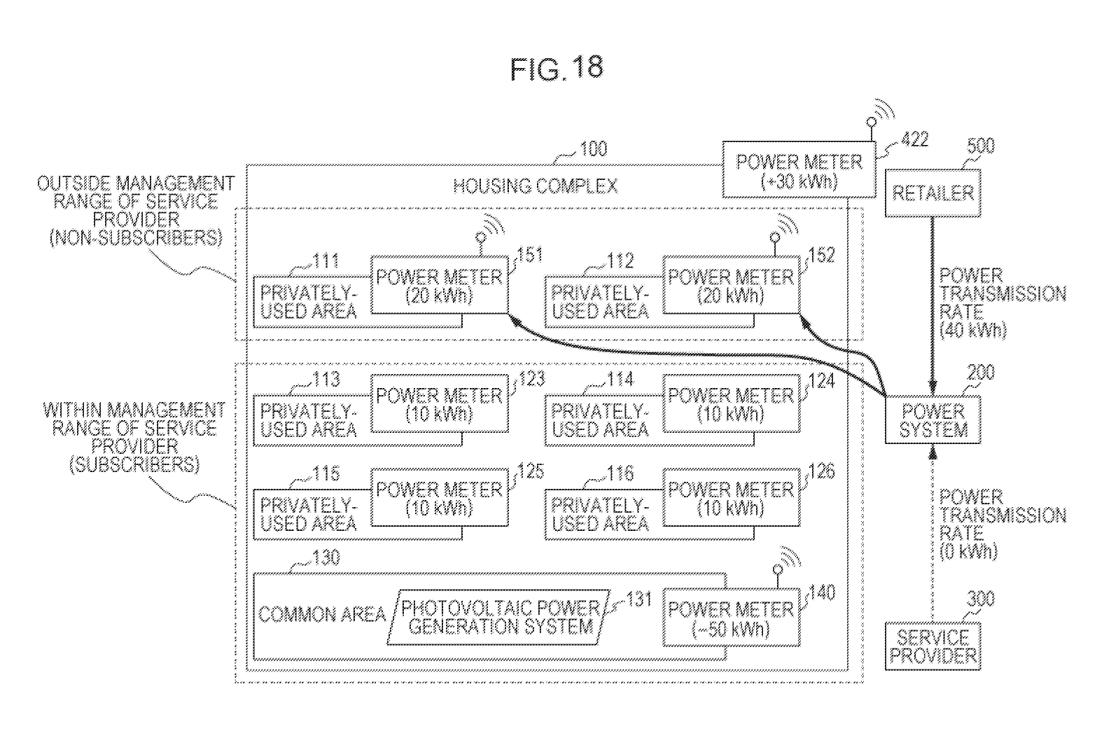

FIG. 18 is a diagram that illustrates a specific example of a case where the power rate calculation system 402 illustrated in FIG. 14 calculates the power rates. The housing complex 100 illustrated in FIG. 18 further has privately-used areas 114 to 116 and power meters 124 to 126 compared to the housing complex 100 illustrated in FIG. 14. Further, the housing complex 100 illustrated in FIG. 18 has power meters 151, 152, and 123 instead of the power meters 121, 122, and 153 in FIG. 14.

The power meters 151 and 152 respectively measure the power amounts of the privately-used areas 111 and 112 in each unit time. Those are smart meters, for example.

Further, in the example of FIG. 18, the tenants of the privately-used areas 111 and 112 are the non-subscribers. That is, the tenants of the privately-used areas 111 and 112 do not select to use the photovoltaic power generation system 131. On the other hand, the tenants of the privately-used areas 113 to 116 are the subscribers. That is, the tenants of the privately-used areas 113 and 116 select to use the photovoltaic power generation system 131.

Further, in the example of FIG. 18, the service provider 300 manages power in the privately-used areas 113 to 116 in which the photovoltaic power generation system 131 is used and power in the photovoltaic power generation system 131 and so forth. Accordingly, the service provider 300 does not manage the privately-used areas 111 and 112 in which the photovoltaic power generation system 131 is not used.

In the example of FIG. 18, because the power amount that is measured by the power meter 422 is positive, the reverse power flow does not occur. However, the power amount that is measured by the power meter 422 is below the total power amount that is measured by the power meters 151 and 152. Thus, the power rate calculation system 402 determines that the photovoltaic power generation system 131 covers the power consumption of the privately-used areas 113 to 116.

That is, in this example, the power system 200 is not used for the power consumption of the privately-used areas 113 to 116 in which the photovoltaic power generation system 131 is used. Accordingly, it is assumed that the power transmission rate does not occur for the privately-used areas 113 to 116. Thus, the power rate calculation system 402 calculates the power transmission rate to be paid from the service provider 300 to the power system 200 as zero yen.

On the other hand, a power amount of 40 kWh is consumed by the privately-used areas 111 and 112 of the non-subscribers. The power amount of 40 kWh is purchased from the power system 200. For example, the non-subscribers of the privately-used areas 111 and 112 pay the power transmission rates that correspond to the power amount of 40 kWh via a retailer 500.

In this example, the power meter 422 indicates a power amount of 30 kWh. That is, the power amount that actually flows from the power system 200 into the housing complex 100 is 30 kWh. The power rate calculation system 402 may deal with 10 kWh that corresponds to the difference between 40 kWh that is the power consumption amount of the privately-used areas 111 and 112 and 30 kWh that is the power amount that flows from the power system 200 into the housing complex 100 as the power amount to be sold to the power system 200.

That is, the power amount that is actually supplied to the privately-used areas 111 and 112 not via the power system 200 may be assumed as the power amount that is supplied to the privately-used areas 111 and 112 via the power system 200.

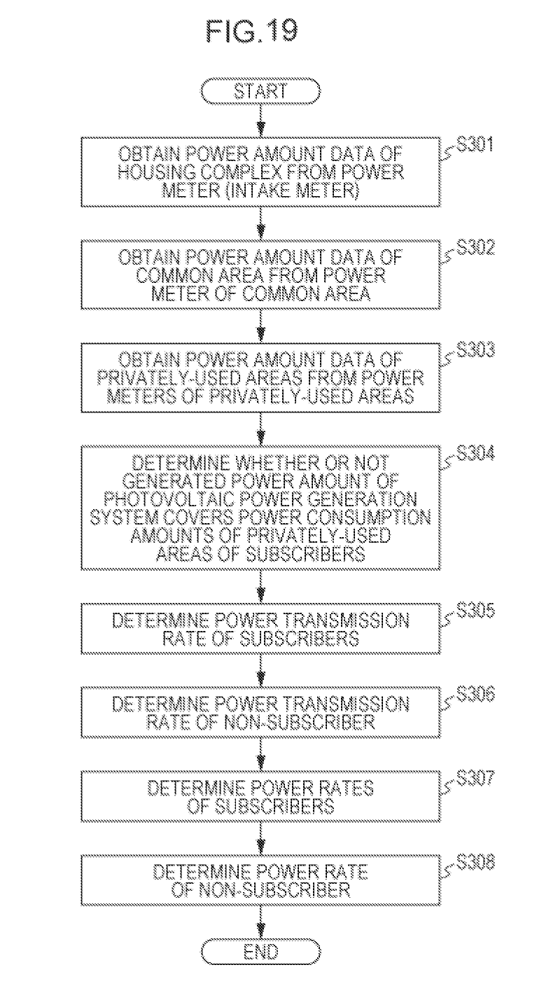

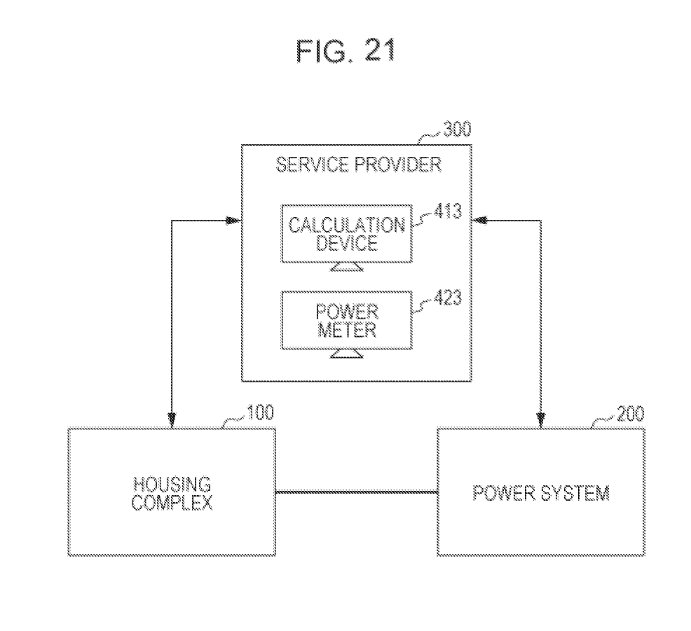

FIG. 19 is a flowchart that illustrates an operation of the power rate calculation system 402 illustrated in FIG. 14. An outline of the operation of the power rate calculation system 402 will be described with reference to FIGS. 16 and 21. Here, although elements illustrated in FIG. 14 are used for the description, the elements may be replaced by elements illustrated in FIG. 18.

The calculation device 412 first obtains the power amount (power amount data) of the housing complex 100 from the power meter 422 (S301). This power amount is the power amount from the power system 200 to the housing complex 100 and is the power amount that is measured by the power meter 422 in each unit time.

The calculation device 412 next obtains the power amount (power amount data) of the common area 130 from the power meter 140 (S302). This power amount is the power amount that is output from the common area 130 and is the power amount that is measured by the power meter 140 in each unit time.

The calculation device 412 next obtains the power amounts (power amount data) of the privately-used area 111, 112, and 113 from the power meters 121, 122, and 153 (S303). Those power amounts are the power consumption amounts of the privately-used areas 111 to 113. Further, the power amount that is obtained from the power meter 153 is the power consumption amount of the privately-used area 113 and is the power amount that is measured by the power meter 153 in each unit time.

The calculation device 412 next determines whether or not the photovoltaic power generation system 131 covers the power consumption of the privately-used areas 111 and 112 of the subscribers based on the power amounts (S304). For example, in a case where the power amount that is measured by the power meter 422 in each unit time is the power amount that is measured by the power meter 153 in each unit time or smaller, the calculation device 412 determines that the photovoltaic power generation system 131 covers the power consumption of the privately-used areas 111 and 112 of the subscribers.

The calculation device 412 next determines the power transmission rate of the subscribers (S305). For example, the calculation device 412 determines the power transmission rate of the subscribers by calculating the power transmission rate while omitting the power consumption amount of the non-subscriber. Further, in this case, the calculation device 412 determines the power transmission rate by selectively applying the plural rate structures based on whether or not the photovoltaic power generation system 131 covers the power consumption of the privately-used areas 111 and 112 of the subscribers.

The calculation device 412 next determines the power transmission rate of the non-subscriber (S306). For example, the calculation device 412 determines the power transmission rate of the non-subscriber by multiplying a predetermined power transmission unit price by the power amount that is obtained from the power meter 153.

The calculation device 412 next determines the power rate of the subscriber (S307). For example, the calculation device 412 determines the power generation rate of the subscriber by multiplying the power amount that is obtained from the power meter 121 or 122 by a predetermined power generation unit price. The calculation device 412 then determines the power rate of the subscriber by adding the power generation rate and the power transmission rate that are calculated with respect to the subscriber.

The calculation device 412 next determines the power rate of the non-subscriber (S308). For example, the calculation device 412 determines the power generation rate of the non-subscriber by multiplying a predetermined power generation unit price by the power amount that is obtained from the power meter 153. The calculation device 412 then determines the power rate of the non-subscriber by adding the power generation rate and the power transmission rate that are calculated with respect to the non-subscriber.

The above operation allows the power rate calculation system 402 to calculate appropriate power rates in accordance with whether the tenants of the privately-used areas 111 to 113 are the subscriber or the non-subscriber. In the above description, the calculation device 412 obtains the power consumption amounts of the privately-used areas 111 to 113 based on the example of FIG. 14. However, the calculation device 412 may obtain the power consumption amounts of the privately-used areas 111 to 116 based on the example of FIG. 18. Further, in this case, the calculation device 412 may obtain the power consumption amounts of the privately-used areas 111 and 112 in each unit time.

As described above, the power rate calculation system 402 according to this embodiment may appropriately calculate the power rates based on whether or not the tenants of the housing complex 100 select to use the photovoltaic power generation system 131. That is, the power rate calculation system 402 allows each of the tenants to select whether or not to use the photovoltaic power generation system 131.

In the example of FIG. 14, the power meter 153 that measures the power consumption amount of the privately-used area 113 of the non-subscriber in each unit time is arranged. However, the power meters 151 and 152 that measure the power consumption amounts of the privately-used areas 111 and 112 of the subscribers in each unit time may be arranged. The power rate calculation system 402 may estimate the power consumption amount of the non-subscriber from the power consumption amounts or the like of the subscribers and thus may appropriately calculate the power rates by a similar method to the above method.

Further, the power meters 121 to 123 may be arranged regardless of the subscriber or the non-subscriber. The power meters 121 to 123 do not measure the power amounts in each unit time but measure the total power amounts in a prescribed period. The calculation device 412 may proportionally divide the total power amounts that are measured in the prescribed period for each unit time. This allows the calculation device 412 to calculate the power rates by a similar method to the above method.

Further, the rate structures A, C, and D described in this embodiment are merely examples, and other rate structures may be used. Substantially same rate structures as the rate structures A, C, and D may be used, or rate structures that are substantially different from the rate structures A, C, and D may be used.

Further, in the operation of FIG. 15, the same rate structure A is applied (S205) to the case where a determination is made that the reverse power flow occurs (Yes in S204) and to the case where a determination is made that the photovoltaic power generation system 131 covers the power consumption of the subscriber (Yes in S208). However, mutually different rate structures may be applied to those cases.

### Third Embodiment

In this embodiment, the power amount from the power system to the housing complex is measured based on power amounts that are obtained from plural power meters installed for plural privately-used areas and a power meter installed for the common area. That is, the power amount from the power system to the housing complex is indirectly measured.

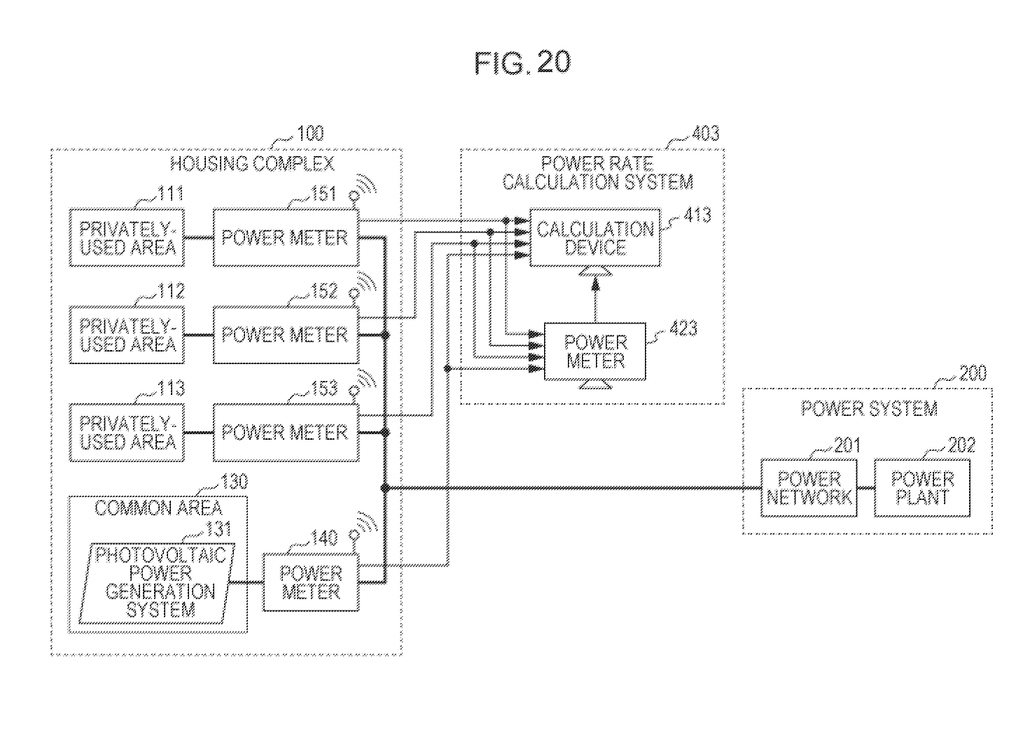

FIG. 20 is a configuration diagram of a power rate calculation system according to this embodiment. A power rate calculation system 403 illustrated in FIG. 20 includes a calculation device 413 and a power meter 423. Those are similar elements to the calculation device 411, the power meter 421, and so forth that are described in the first embodiment. The power meter 423 according to this embodiment indirectly measures the power amount from the power system 200 to the housing complex 100.

Further, in an example of FIG. 20, the power meters 151 to 153 respectively measure the power consumption amounts of the privately-used areas 111 to 113 in each unit time. The power meters 151 to 153 are smart meters, for example.

Further, in the example of FIG. 20, the power meter 423 obtains the power amounts (power amount data) that are measured by the power meters 140 and 151 to 153 in each unit time. In this case, the power meter 423 may obtain the power amounts from the power meters 140 and 151 to 153 via a wired or wireless communication network. The power meter 423 measures the power amount from the power system 200 to the housing complex 100 based on the power amounts that are measured by the power meters 140 and 151 to 153 in each unit time.

For example, in a case where the power amounts that are measured by the power meters 140, 151, 152, and 153 are p, h1, h2, and h3, respectively, in a target unit time, the power meter 423 calculates the power amount i from the power system 200 to the housing complex 100 by p+h1+h2+h3.

The calculation device 413 may calculate the power rates based on the power amount or the like that is measured by the power meter 423, similarly to the calculation device 411 of the first embodiment or the calculation device 412 of the second embodiment.

FIG. 21 is an arrangement diagram of the calculation device 413 and the power meter 423 of the power rate calculation system 403 illustrated in FIG. 20. For example, the calculation device 413 and the power meter 423 are arranged in the location of the service provider 300. That is, the power meter 423 may not be arranged at the gateway of power of the housing complex 100. The power meter 423 may measure the power amount from the power system 200 to the housing complex 100 even in a case where the power meter 423 is arranged in the location of the service provider 300.

In an example of FIG. 21, the calculation device 413 and the power meter 423 are arranged in the location of the service provider 300. However, arrangement positions of the calculation device 413 and the power meter 423 are not limited to the location of the service provider 300. The calculation device 413 and the power meter 423 may be arranged in any location.

The calculation device 413 and the power meter 423 may be portable. In this case, the calculation device 413 and the power meter 423 may obtain the power amounts from the power meters 140 and 151 to 153 via a wireless communication network.

Further, the calculation device 413 may include the power meter 423, or the power meter 423 may include the calculation device 413. The calculation device 413 and the power meter 423 may be included in a single computer.

As described above, the power rate calculation system 403 according to this embodiment measures the power amount from the power system 200 to the housing complex 100 in each unit time based on the power amounts that are measured by the power meters 140 and 151 to 153 in each unit time. This allows the power rate calculation system 403 to appropriately calculate the power rates even in a case where the power meter 423 is not arranged inside or in a vicinity of the housing complex 100.

In this embodiment, the power meters 151 to 153 may measure the respective power consumption amounts of the privately-used areas 111 to 113 in each unit time. Further, the calculation device 413 of the power rate calculation system 403 may calculate the power amount from the power system 200 and the power amount from the photovoltaic power generation system 131 in the power consumption amounts of the privately-used areas 111 to 113 based on the power amounts that are measured by the power meters 140 and 151 to 153.

Accordingly, the calculation device 413 of the power rate calculation system 403 may appropriately calculate the power rates for each unit time in accordance with the proportions of use of the power amount from the photovoltaic power generation system 131. In this case also, the calculation device 413 may selectively apply the plural rate structures in accordance with whether or not the photovoltaic power generation system 131 covers the power consumption of the housing complex 100 in each unit time.

### Fourth Embodiment

In this embodiment, a simpler configuration than the first embodiment is used. More specifically, the power meter of the common area is omitted in this embodiment.

FIG. 22 is a configuration diagram of a power rate calculation system according to this embodiment. A power rate calculation system 404 illustrated in FIG. 22 includes a calculation device 414 and a power meter 424. Those are similar elements to the calculation device 411, the power meter 421, and so forth that are described in the first embodiment. The calculation device 414 according to this embodiment calculates the power rates by following a calculation method that is partially different from the calculation device 411 described in the first embodiment. Further, in this embodiment, the power meter that measures the power amount output from the common area 130 is not arranged.

For example, the calculation device 414 according to this embodiment obtains the power amount that is measured by the power meter 424 in a target unit time. Here, the power amount that is measured by the power meter 424 in the target unit time (the power amount of the power meter 424) is the power amount from the power system 200 in the target unit time.

In a case where the power amount of the power meter 424 is larger than zero, the calculation device 414 calculates the cost in the target unit time by proportionally dividing the power amount of the power meter 424 for the privately-used areas 111 to 113 based on the power consumption amounts that are measured by the power meters 121 to 123. That is, in this case, the calculation device 414 calculates the cost in the target unit time by proportionally dividing the power amount from the power system 200 for the privately-used areas 111 to 113 in accordance with the power consumption amounts of the privately-used areas 111 to 113.

In this case, the power amount that is consumed by the common area 130 in the target unit time in the power amount from the power system 200 is proportionally divided for the privately-used areas 111 to 113. Accordingly, the cost that corresponds to the power amount consumed by the common area 130 in the target unit time is also proportionally divided for the privately-used areas 111 to 113.

On the other hand, in a case where the power amount of the power meter 424 is zero or smaller, the calculation device 414 calculates the cost in the target unit time while assuming that power from the power system 200 is not used in the privately-used areas 111 to 113. For example, in this case, the calculation device 414 calculates the power transmission cost for the target unit time as zero.

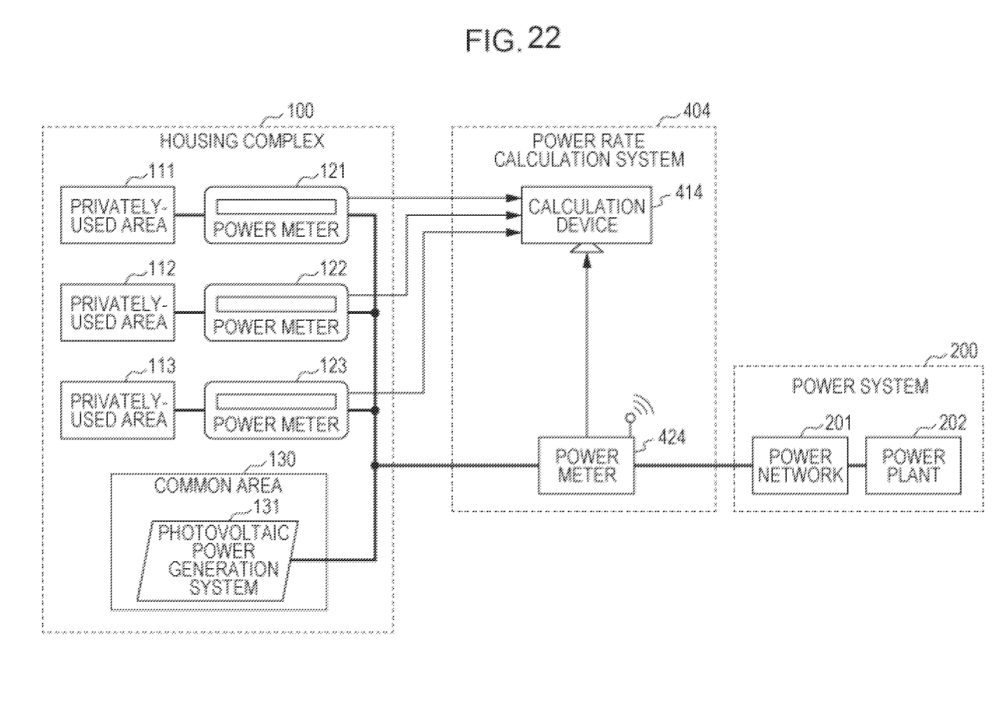

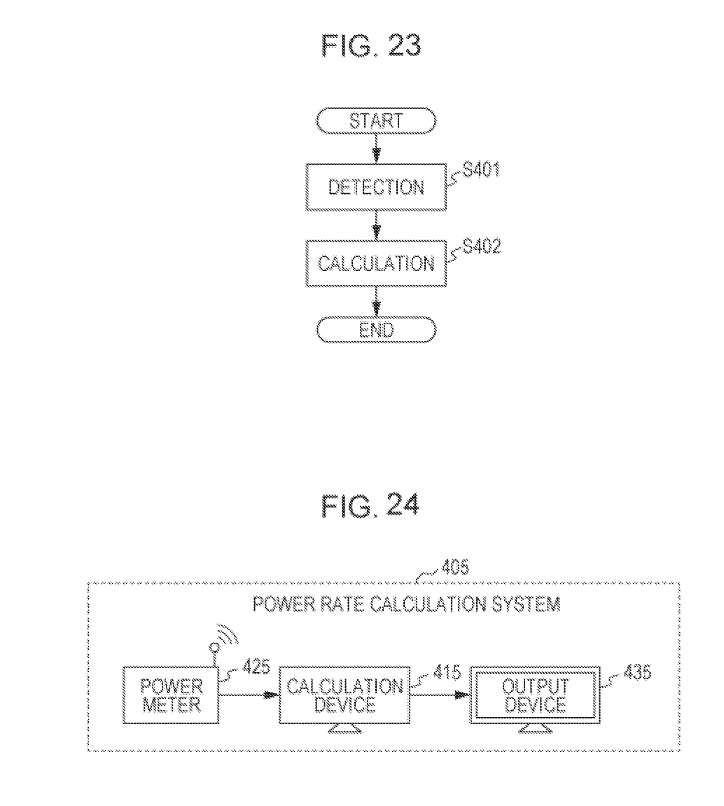

FIG. 23 is a flowchart that illustrates an operation of the power rate calculation system 404 illustrated in FIG. 22. The power meter 424 first detects whether or not the generated power amount of the photovoltaic power generation system 131 is larger than or equal to the power consumption amounts of the privately-used areas 111 to 113 and the common area 130 in each unit time in a prescribed period (S401).

Next, the calculation device 414 calculates the power rates from the power amounts of the privately-used areas 111 to 113 by applying a first rate structure to the unit time in which the generated power amount is larger than or equal to the power consumption amounts and applying a second rate structure to the unit time in which the generated power amount is smaller than the power consumption amounts (S402). This allows the power rate calculation system 404 to appropriately calculate the power rates in accordance with whether or not the photovoltaic power generation system 131 covers the power consumption of the housing complex 100.

Although FIG. 23 illustrates the operation of the power rate calculation system 404, the operations of the power rate calculation systems 401 to 403 of the first to third embodiments are similar to the operation illustrated in FIG. 23. That is, in the above description, the calculation device 414 may be replaced by any of the calculation devices 411 to 413, and the power meter 424 may be replaced by any of the power meters 421 to 423.

As described above, the power rate calculation system 404 according to this embodiment selectively applies the plural rate structures in accordance with whether or not the power consumption of the housing complex 100 is covered by the photovoltaic power generation system 131 of the housing complex 100. Accordingly, the power rate calculation system 404 may reflect, in the power rates, use of the photovoltaic power generation system 131 in the power consumptions of the privately-used areas 111 to 113.

### Fifth Embodiment

In this embodiment, an output device that outputs the power rate will be described. The output device described in this embodiment is arbitrarily added to the first to fourth embodiments.

FIG. 24 is a configuration diagram of a power rate calculation system according to this embodiment. A power rate calculation system 405 illustrated in FIG. 24 includes a calculation device 415, a power meter 425, and an output device 435. The calculation device 415 and the power meter 425 are similar elements to the calculation device 411 and the power meter 421 or the like that are described in the first embodiment. The power rate calculation system 405 according to this embodiment further includes the output device 435 compared to the power rate calculation system 401 or the like that is described in the first embodiment.

The output device 435 is a device that outputs the power rate (power rate information) that is calculated by the calculation device 415. The output device 435 may be a printer that outputs paper on which the power rate is printed or may be a display device that displays the power rate on a screen. Further, the output device 435 may be a communication device that transmits the power rate via a communication network.

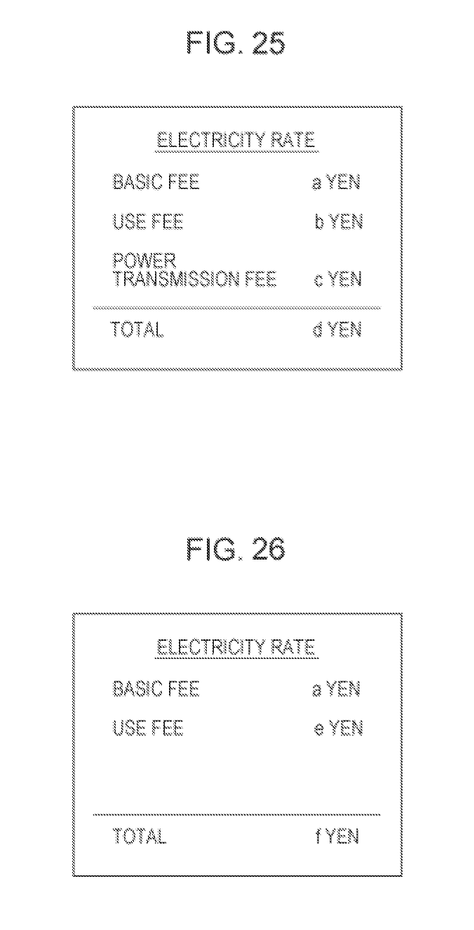

FIG. 25 is a diagram that illustrates a first output example of the power rate that is output by the power rate calculation system 405 illustrated in FIG. 24. FIG. 25 illustrates an electricity rate that includes a basic fee, a use fee, and a power transmission fee. The basic fee is a fixed rate that is predetermined regardless of a use amount of power. The use fee is a rate that changes in accordance with the use amount of power. Here, the use fee corresponds to the power generation rate. The power transmission fee is a rate that changes in accordance with the transmission amount of power. Here, the power transmission fee corresponds to the power transmission rate. Further, the electricity rate corresponds to the power rate.

As the example in FIG. 25, the output device 435 may output the power rate with the power generation rate and the power transmission rate in the power rate being separated. This allows the power rate calculation system 405 to clearly indicate the power transmission rate that corresponds to the power amount that is transmitted from the power system 200.

FIG. 26 is a diagram that illustrates a second output example of the power rate that is output by the power rate calculation system 405 illustrated in FIG. 24. In the example of FIG. 26, the power transmission fee is not indicated compared to the example in FIG. 25. Because power is not transmitted from the power system 200 in a case where power of the power system 200 is not used, the output device 435 may not output the power transmission fee as the example of FIG. 26.

Alternatively, the output device 435 may output the power transmission fee as zero yen in an output format illustrated in FIG. 25 in a case where power of the power system 200 is not used. Alternatively, in the example of FIG. 26, the use fee may include the power generation rate and the power transmission rate. In this case, the use fee changes in accordance with the transmission amount of power from the power system 200.

As described above, the power rate calculation system 405 according to this embodiment may appropriately output the power rate that changes in accordance with the power transmission amount.

As described in the above plural embodiments, the power rate calculation system selectively applies the plural rate structures in accordance with whether or not the power consumption is covered by the photovoltaic power generation system. Accordingly, the power rate calculation system may reflect, in the power rates, use of the photovoltaic power generation system in the power consumptions of the privately-used areas.

In the above plural embodiments, the photovoltaic power generation system is used. However, a power generation system is not limited to the photovoltaic power generation system, and another power generation system such as a fuel cell system or a wind power generation system may be used. Further, a storage battery (storage battery system) that generates power by discharging electricity may be used as the power generation system. Alternatively, a combination thereof may be used as the power generation system.

Further, the power meter that measures the power amount from the power system to the housing complex in each unit time may be a detection device that detects whether or not the generated power amount of the power generation system of the housing complex is larger than or equal to the power consumption amount of the housing complex in each unit time. That is, a specific power amount from the power system to the housing complex may not be measured. For example, a detection device that detects presence or absence of the reverse power flow may be used. Further, the detection device that detects whether or not the generated power amount is larger than or equal to the power consumption amount may be a monitoring device that monitors whether or not the generated power amount is the power consumption amount.

In a case where the detection device as described above is used, the power rate calculation system selectively applies the plural rate structures in accordance with whether or not the power consumption is covered by the photovoltaic power generation system.

For example, a value of zero is applied to the power transmission cost for the unit time in which the generated power amount of the power generation system of the housing complex is larger than or equal to the power consumption amount of the housing complex, and (unit time/prescribed period)×(power transmission cost of power system) is applied to the power transmission cost for the unit time in which the generated power amount is smaller than the power consumption amount. The power rate calculation system then calculates the power transmission rate that is included in the power generation rate by multiplying the total of plural power transmission costs that are applied to the prescribed period by the power consumption amounts of the privately-used areas. This allows the power rate calculation system to reflect use of the power generation system in the power rates.

Further, detecting whether or not the generated power amount of the power generation system of the housing complex is larger than or equal to the power consumption amount of the housing complex is equivalent to detecting whether or not the power amount that flows from the power system into the whole housing complex is zero or smaller. Accordingly, detecting whether or not the generated power amount of the power generation system of the housing complex is larger than or equal to the power consumption amount of the housing complex may be considered as detecting whether or not the power amount that flows from the power system into the whole housing complex is zero or smaller.

Further, the power rate calculation system may include arbitrary elements that are included in the housing complex or the power system. Further, the elements that are included in the power rate calculation systems in the above plural embodiments may be omitted from the power rate calculation systems.

Further, the power rate calculation system calculates the power rates of the privately-used areas of the facility that has the common area in which the power generation system is installed. In the above plural embodiments, the housing complex is described as an example of the facility. However, the facility is not limited to the housing complex. For example, the facility may be a multi-tenant building. In addition, the tenants may be households or stores. In a case where the facility is the housing complex, the tenants are households, and the households reside in the privately-used areas for the tenants.

Further, in the facility such as the housing complex or the multi-tenant building, each of the plural privately-used areas is occupied by the tenant, and the common area is used in common by the plural tenants. The privately-used area may be a privately-owned area that is privately owned by the tenant. The common area may be a shared area that is shared by the plural tenants. The privately-used areas and the common area may correspond to privately-owned areas and a common area that are provided by laws or may be areas that are defined by other standards. The privately-used area is mainly used by the tenant of the privately-used area. However, the privately-owned area may not necessarily be exclusively used.

Further, in the above plural embodiments, an example where surplus power is sold is described. However, surplus power may not be sold but may only reversely flow into the power system.

In the above embodiments, the elements may be realized by configuring those with dedicated hardware or by executing software programs that are suitable for the elements. A program execution unit such as a CPU or a processor reads out and executes software programs that are recorded in a recording medium such as a hard disk or a semiconductor memory, and the elements may thereby be realized. Here, the software that realizes the power rate calculation system or the like of the above embodiments may be a program as follows:

That is, this program causes a computer to execute a power rate calculation method of calculating power rates of plural privately-used areas in a facility that has the plural privately-used areas, plural first power meters that measure plural first power amounts that are consumed by the plural privately-used areas in a prescribed period, and a common area in which a power generation system is installed, the power rate calculation method including: a detection step of detecting whether or not a second power amount that is generated by the power generation system is larger than or equal to a third power amount that is consumed by the plural privately-used areas and the common area in each unit time in the prescribed period; and a calculation step of calculating the power rates in the prescribed period from the plural first power amounts by applying a first rate structure to a first unit time in which detection is made that the second power amount is larger than or equal to the third power amount and by applying a second rate structure that is different from the first rate structure to a second unit time in which detection is made that the second power amount is smaller than the third power amount.

Further, the elements may be circuits. Those circuits may configure a single circuit as a whole or may be separate circuits. Further, each of those circuits may be a general-purpose circuit or may be a dedicated circuit.

In the foregoing, a description has been made about the power rate calculation system according to one or plural aspects based on the embodiments. However, the present disclosure is not limited to the embodiments. Modes in which various kinds of modifications conceived by persons having ordinary skill in the art are applied to this embodiment and modes that are configured by combining elements in different embodiments may be included in the scope of the one or plural aspects unless the modes depart from the gist of the present disclosure.

For example, in the above embodiments, a process that is executed by a particular processing unit may be executed by another processing unit. Further, orders of plural processes may be changed, or plural processes may simultaneously be executed.

The present disclosure is usable for a power rate calculation system that calculate power rates of privately-used areas of a facility in which a power generation system is installed in a common area and is applicable to a power rate billing system, a power rate guidance system, a power rate display system, a power rate transmission system, a power rate output system, and so forth, for example.

What is claimed is:

1. A power rate calculation method for used in a facility that has the plurality of privately-used areas and a common area, one or more power generators are installed in the common area, the method comprising:
obtaining a plurality of first power amounts consumed by each of the privately-used areas in a prescribed period;
detecting whether or not a second power amount generated by the one or more power generators is larger than or equal to a third power amount consumed by both of the plurality of privately-used areas and the common area in each unit time in the prescribed period; and
calculating the power rates in the prescribed period from the plurality of first power amounts by applying a first rate structure when the second power amount is larger than or equal to the third power amount and by applying a second rate structure that is different from the first rate structure when the second power amount is smaller than the third power amount.

2. The power rate calculation method according to claim 1, wherein
the first rate structure has a lower power transmission cost than that of the second rate structure.

3. The power rate calculation method according to claim 1, wherein
a power transmission cost of the first rate structure is free and a power transmission cost of the second rate structure is charged.

4. The power rate calculation method according to claim 1, wherein
the first rate structure includes a power generation cost of the one or more power generators and the second rate structure includes the power generation cost of a power system.

5. The power rate calculation method according to claim 1, further comprising:
measuring a fourth power amount from the power system to the facility in each unit time in the prescribed period and;
detecting whether or not the second power amount is larger than or equal to the third power amount based on the fourth power.

6. The power rate calculation method according to claim 1, further comprising:
measuring a fifth power amount input to the common area in each unit time; and
calculating the power rates based on the fifth power amount.

7. The power rate calculation method according to claim 6, wherein
applying the second rate structure when the fifth power amount that is zero or smaller, and a third rate structure that is different from the first rate structure and the second rate structure when the fifth power amount is larger than zero.

8. The power rate calculation method according to claim 6, wherein,
detecting whether or not the second power amount is larger than or equal to the third power amount based on the plurality of first power amounts and the fifth power amount in each unit time.

9. The power rate calculation method according to claim 1, wherein
calculating the power rates based on whether or not each of a plurality of tenants of the plurality of respective privately-used areas selects to use the one or more power generators.

10. The power rate calculation method according to claim 9, wherein
applying the first rate structure and the second rate structure when the power rate of the privately-used area is calculated for the tenant that selects to use the one or more power generators, and a fourth rate structure that is different from the first rate structure and the second rate structure when the power rate of the privately-used area is calculated for the tenant that does not select to use the one or more power generators.

11. A power rate calculation device for used in a facility that has the plurality of privately-used areas and a common area, one or more power generators are installed in the common area, the device comprising:
one or more memories; and circuitry operative to:
obtain a plurality of first power amounts consumed by each of the privately-used areas in a prescribed period;
detect whether or not a second power amount generated by the one or more power generators is larger than or equal to a third power amount consumed by both of the plurality of privately-used areas and the common area in each unit time in the prescribed period; and
calculate the power rates in the prescribed period from the plurality of first power amounts by applying a first rate structure when the second power amount is larger than or equal to the third power amount and by applying a second rate structure that is different from the first rate structure when the second power amount is smaller than the third power amount.
